(19) United States
(12) Patent Application Publication
(10) Pub. No.: US 2025/0359005 A1
(43) Pub. Date: Nov. 20, 2025

(54) FRONTSIDE AND BACKSIDE BIT LINES IN A MEMORY ARRAY

(71) Applicant: Taiwan Semiconductor Manufacturing Company, Ltd., Hsin-Chu (TW)

(72) Inventors: Ping-Wei Wang, Hsin-Chu (TW); Jui-Lin Chen, Taipei City (TW)

(21) Appl. No.: 19/286,050

(22) Filed: Jul. 30, 2025

Related U.S. Application Data
(63) Continuation of application No. 18/629,474, filed on Apr. 8, 2024.
(60) Provisional application No. 63/599,256, filed on Nov. 15, 2023.

(51) Int. Cl. H10B 10/00

(52) U.S. Cl. CPC H10B 10/125

(57) ABSTRACT

A semiconductor device according to the present disclosure includes a logic cell and a memory array including a plurality of memory cells. The memory cells and the logic cell are arranged in a row, and a first plurality of the memory cells are positioned closer to the logic cell than a second plurality of the memory cells. A frontside interconnect structure is disposed over the memory cells and includes a frontside bit line. The frontside bit line is coupled to each of the memory cells arranged in the row. A backside interconnect structure is disposed under the memory cells and includes a backside bit line. The backside bit line is coupled to at least the first plurality of the memory cells. The frontside bit line is coupled to the backside bit line through a source/drain feature of a pass-gate transistor of one of the first plurality of the memory cells.

### PRIORITY DATA

This is a continuation application of U.S. patent application Ser. No. 18/629,474, filed Apr. 8, 2024, which claims benefit of U.S. Provisional Patent Application Ser. No. 63/599,256, filed Nov. 15, 2023, each of which is incorporated herein by reference in its entirety.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Such scaling down in integrated circuit technology has not only complicated the manufacturing processes but also raised specific challenges in the design and functionality of memory arrays within memory devices. For example, operations of memory cells at different locations in a memory array raise a need for tailored structural designs for signal lines (e.g., bit lines) coupled to the memory cells. The traditional approach of employing bit lines on the frontside of the memory cells with one uniform width across all the cells in the same row is increasingly inadequate, as it does not optimally address the varying performance demands of these memory cells. Relying solely on frontside bit lines with a uniform width deployed in a memory array can lead to suboptimal performance, where the specific needs of memory cells at different locations in a memory array are not fully met. This discrepancy highlights the need for a differentiated approach in bit line architecture to enhance the overall efficiency and performance of memory devices, particularly in the context of advanced semiconductor technologies.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a block diagram of a semiconductor device having a memory macro, according to various aspects of the present disclosure.

FIG. 2 is a block diagram of a memory macro having a memory array, according to various aspects of the present disclosure.

FIG. 3 is a circuit schematic of a single-port static random-access memory (SRAM) cell, according to various aspects of the present disclosure.

FIG. 4 illustrates a cross-sectional view of various layers of a memory device, according to various aspects of the present disclosure.

FIGS. 5 and 6 illustrate a layout including device layer and metal layers, respectively, of the single-port SRAM cell as in FIG. 3, according to various aspects of the present disclosure.

FIG. 7 illustrates a layout including device layer and metal layers of a 2×2 SRAM array, according to various aspects of the present disclosure.

FIG. 8 illustrates a cross-sectional view of a semiconductor device along a cut line A-A in FIG. 7, according to various aspects of the present disclosure.

FIG. 9 illustrates an alternative layout including device layer and metal layers of a 2×2 SRAM array, according to various aspects of the present disclosure.

FIG. 10 illustrates a cross-sectional view of a semiconductor device along a cut line A-A in FIG. 9, according to various aspects of the present disclosure.

FIGS. 11, 12, 13, 14, 15, and 16 illustrate layouts including frontside bit lines and backside bit lines in a memory macro, according to various aspects of the present disclosure.

FIG. 17 is a circuit schematic of a two-port static random-access memory (SRAM) cell, according to various aspects of the present disclosure.

FIGS. 18 and 19 illustrate a layout including device layer and metal layers, respectively, of the two-port SRAM cell as in FIG. 17, according to various aspects of the present disclosure.

FIG. 20 illustrates a layout including frontside bit lines and backside bit lines in a memory macro, according to various aspects of the present disclosure.

FIG. 21 illustrates a cross-sectional view of a semiconductor device along a cut line B-B in FIG. 20, according to various aspects of the present disclosure.

FIGS. 22, 23, and 24 illustrate alternative layouts including frontside bit lines and backside bit lines in a memory macro, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. When describing aspects of a transistor, source/drain region(s) may refer to a source or a drain, individually or collectively, dependent upon the context.

Static Random Access Memory (SRAM) is a semiconductor memory that retains data statically as long as it is powered. Unlike dynamic RAM (DRAM), SRAM is faster and more reliable, eliminating the need for constant refreshing. An SRAM macro includes memory cells and logic cells. The memory cells are also referred to as bit cells, and are configured to store memory bits. The memory cells may be arranged in rows and columns in forming an array. The logic cells may be standard cells (STD cells), such as inventor (INV), AND, OR, NAND, NOR, Flip-flip, SCAN and so on. The logic cells are disposed around the memory cells, and are configured to implement various logic functions.

Between the memory cells and logic cells, multilayer interconnect structures provide metal tracks (metal lines) for interconnecting power lines and signal lines. Memory cells at different locations may have different structural design needs to achieve optimal performance. For instance, a memory cell located close to logic cells may need a structural design for its bit line that minimizes resistance as other memory cells in the same row and thus coupled to the same bit line will also “see” the resistance in series. A bit line with a low resistance affords a larger voltage headroom. In contrast, a memory cell located far away from the logic cells may need a structural design for its bit line that minimizes latency with reduced parasitic capacitance as such a memory cell generally suffers from a reduced circuit speed. Meanwhile, with the increasing downscaling of SRAM cells, available layout area on the frontside of an SRAM array becomes limited. Consequently, bit lines tend to be designed with reduced dimensions and are more closely packed. This inevitably leads to increased resistance and parasitic capacitance. Thus, relying solely on bit lines disposed on the frontside of an SRAM array with a uniform bit line width across different memory cells might result in suboptimal performance, as it does not meet the unique requirements of each memory cell.

The present disclosure introduces a bit line structure providing bit lines disposed on the frontside of an SRAM array (referred to as frontside bit lines) together with bit lines disposed on the backside of the SRAM array (referred to as backside bit lines). Widths of the frontside and backside bit lines may be different. Further, each of the frontside and backside bit lines may have a non-uniform width. In one embodiment, an SRAM array may feature frontside bit lines with a uniform width and backside bit lines with two or more widths for memory cells at different distances from input/output (I/O) periphery, thereby enhancing circuit performance.

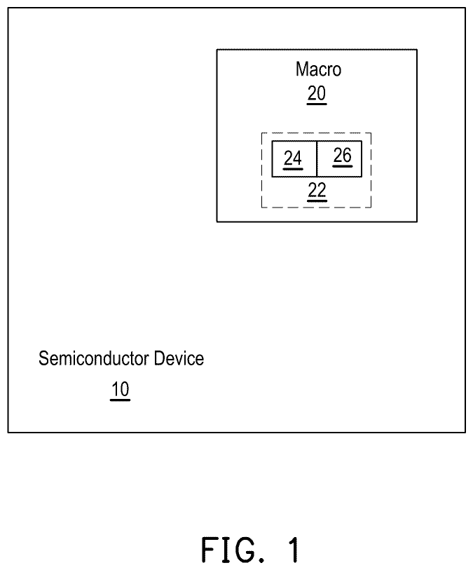

Reference now is made to FIG. 1. FIG. 1 is a simplified block diagram of a semiconductor device (or IC) 10, in accordance with some embodiments of the present disclosure. The semiconductor device 10 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistors (PFETs), n-type field effect transistors (NFETs), FinFET, gate-all-around (GAA) transistors (such as nanosheet FETs or nanowire FETs), other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. The exact functionality of the semiconductor device 10 is not a limitation to the provided subject matter.

The semiconductor device 10 includes a memory macro (hereinafter, macro) 20. In some embodiments, the macro 20 is a static random-access memory (SRAM) macro, such as a single-port SRAM macro, a dual-port SRAM macro, or other types of SRAM macro. However, the present disclosure contemplates embodiments, where macro 20 is another type of memory, such as a dynamic random-access memory (DRAM), a non-volatile random access memory (NVRAM), a flash memory, or other suitable memory. FIG. 1 has been simplified for the sake of clarity to better understand the inventive concepts of the present disclosure. Additional features can be added in the macro 20, and some of the features described below can be replaced, modified, or eliminated in other embodiments of the macro 20.

In some embodiments, the macro 20 includes memory cells and peripheral circuits. The memory cells are also referred to as bit cells, and are configured to store memory bits. The peripheral cells are also referred to as logic cells that are disposed around the bit cells, and are configured to implement various logic functions. The logic functions of the logic cells include, for example, write and/or read decoding, word line selecting, bit line selecting, data driving and memory self-testing. The logic functions of the logic cells described above are given for the explanation purpose. Various logic functions of the logic cells are within the contemplated scope of the present disclosure. In the illustrated embodiment, the macro 20 includes a circuit region 22 in which at least a memory array 24 and at least a peripheral circuit 26 are positioned in close proximity to each other. The memory array 24 includes many memory cells arranged in rows and columns. The peripheral circuit 26 includes logic cells. Generally, the peripheral circuit 26 may include many logic cells to provide read operations and/or write operations to the memory cells in the memory array 24. The macro 20 may include more than one memory array 24 and more than one peripheral circuit 26. Transistors in the one or more memory arrays 24 and the one or more peripheral circuits 26 may be implemented with various PFETs and NFETs such as planar transistors or non-planar transistors including various FinFET transistors, GAA transistors, or a combination thereof. GAA transistors refer to transistors having gate electrodes surrounding transistor channels, such as vertically-stacked gate-all-around horizontal nanowire or nanosheet MOSFET devices. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

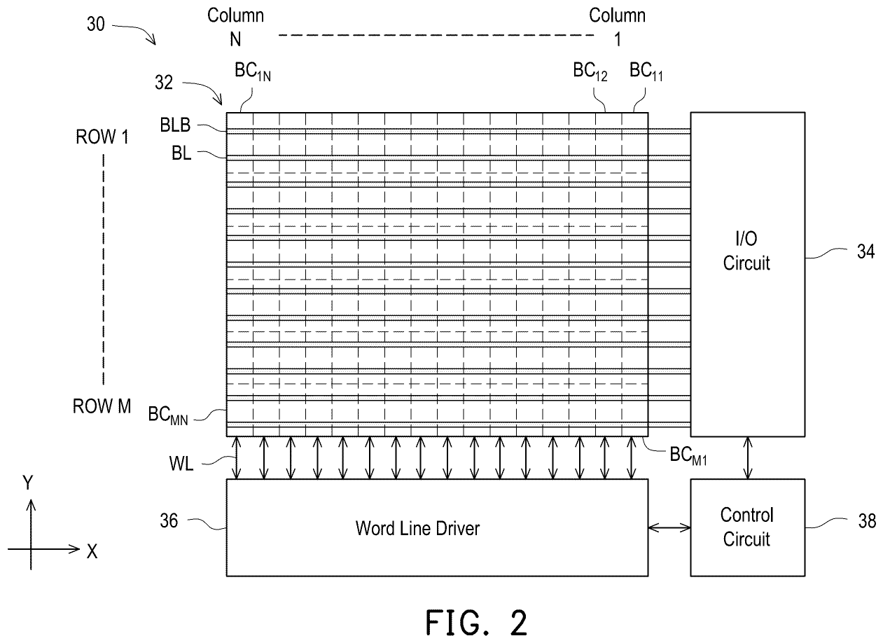

FIG. 2 shows a portion of a macro 30, which includes a memory array 32, an input/output (I/O) circuit 34, a word line driver 36, and a control circuit 38. In some embodiments, the macro 30 can be implemented as the circuit region 22 in FIG. 1; the memory array 32 can be implemented as the memory array 24 in FIG. 1; and the input/output (I/O) circuit 34, the word line driver 36, and the control circuit 38 collectively can be implemented as the peripheral circuit 26 in FIG. 1. FIG. 2 has been simplified for the sake of clarity to better understand the inventive concepts of the present disclosure. Additional features can be added in the macro 30, and some of the features described below can be replaced, modified, or eliminated in other embodiments of the macro 30.

The memory array 32 includes memory cells arranged in rows and columns. In the illustrated embodiment, the memory cells are arranged from Row 1 to Row M each extending along a first direction (here, in the X-direction) and in Column 1 to Column N each extending along a second direction (here, in the Y-direction), where M and N are positive integers. Generally, N is a power of 2, such as 64, 128, 256, 512, and so on. The present disclosure contemplates N being any other integer. For simplicity of illustration, only a few rows and a few columns and the corresponding memory cells are shown in FIG. 2. Each memory cell stores one bit of data. Accordingly, a memory cell is also referred to as a bit cell or denoted as BCₘₙ according to its location in the memory array 32, where m representing the row and n representing the column. For example, BC₁₁ represents the memory cell located in the first row (Row 1) and the first column (Column 1), which is the memory cell closest to the I/O circuit 34 in the first row (Row 1); BC₁₂ represents the memory cell located in the first row (Row 1) and the second column (Column 2), which is the memory cell second closest to the I/O circuit 34 in the first row (Row 1); BC_{1N} represents the memory cell located in the first row (Row 1) and the last column (Column N), which is the memory cell farthest away from the I/O circuit 34 in the first row (Row 1); and BC_{MN} represents the memory cell located in the last row (Row M) and the last column (Column N), which is the memory cell farthest away from the I/O circuit 34 in the last row (Row M). A memory cell BCₘₙ may be referred to as a BC for simplicity.

Rows 1 to M each include a bit line pair extending along the X-direction, such as a bit line (BL) and a bit line bar (BLB) (also referred to as a complementary bit line), that facilitate reading data from and/or writing data to respective memory cells BC in true form and complementary form on a row-by-row basis. Columns 1 to M each includes a word line (WL) that facilitates access to respective memory cells BC on a column-by-column basis. Each memory cell BC is electrically connected to a respective BL, a respective BLB, and a respective WL.

The I/O circuit 34 is coupled to the memory array 32 through the bit line pairs BL and BLB. The I/O circuit 34 is configured to select one of the rows in the memory array 32, and to provide bit line signal on one of the bit line pairs that is arranged on the selected row, in some embodiments. The bit line signal is transmitted through the selected bit line pair BL and BLB to the corresponding memory cells BC, for writing the bit data into, or reading the bit data from, the corresponding memory cells BC.

The word line driver 36 is coupled to the memory array 32 through the word lines WL. The word line driver 36 is configured to select one of the columns in the memory array 32, and to provide word line signal on one of the word lines WL that is arranged on the selected column, in some embodiments. The word line signal is transmitted through the selected word line WL to the corresponding memory cells BC, for writing the bit data into, or reading the bit data from, the corresponding memory cells BC.

The control circuit 38 is coupled to and disposed next to both of the I/O circuit 34 and the word line driver 36. The control circuit 38 configures the I/O circuit 34 and the word line driver 36 to generate one or more signals to select at least one WL and at least one bit line pair (here, BL and BLB) to access at least one of memory cells BC for read operations and/or write operations. The control circuit 38 includes any circuitry suitable to facilitate read/write operations from/to memory cells BC, including but not limited to, a column decoder circuit, a row decoder circuit, a column selection circuit, a row selection circuit, a read/write circuit (for example, configured to read data from and/or write data to memory cells BC corresponding to a selected bit line pair (in other words, a selected column)), other suitable circuit, or combinations thereof. In some embodiments, the control circuit 38 is implemented by a processor. In some other embodiments, the control circuit 130 is integrated with a processor. The processor is implemented by a central processing unit (CPU), a multi-processor, a distributed processing system, an application specific integrated circuit (ASIC), and/or a suitable processing unit.

In a write or read operation, at least one bit line pair and at least one word line WL are respectively selected by the I/O circuit 34 and the word line driver 36. When one word line WL on one corresponding column is selected, the bit line signal is transmitted from the I/O circuit 34 to one corresponding memory cell BC, or the bit line signal is transmitted from the memory cell BC to the I/O circuit 34. A memory cell located far away from the I/O circuit 34, such as memory cell BC_{1N}, is more sensitive to latency impacted by parasitic capacitance. However, the transmitting path along the signal lines in the bit line pair (here, BL and BLB extending through Columns 1 to N) to such a memory cell is relatively long and easily introduces a large parasitic capacitance. Therefore, a memory cell located far away from the I/O circuit 34 may want to “see” a narrower signal line thus a reduced parasitic capacitance. In a comparison, for a memory cell located near the I/O circuit 34, such as memory cell BC₁₁, the transmission path along the signal lines in the bit line pair (here, BL and BLB extending through Columns 1 to N) is relatively short, and the memory cell is less sensitive to parasitic capacitance. Therefore, a memory cell located close to the I/O circuit 34 may want to “see” a wider signal line thus an enlarge voltage headroom. Accordingly, memory cells located at different columns of a memory array have different requirements on dimensions of the signal lines, such as widths of the BL and BLB in the bit line pair, for further performance optimization.

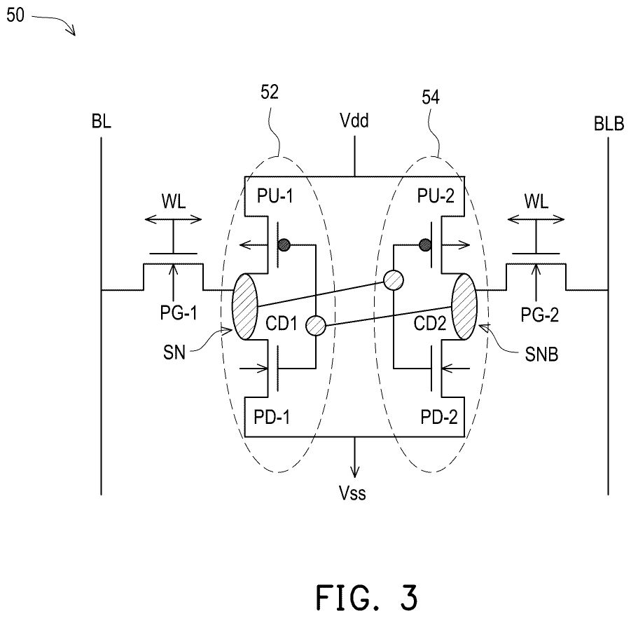

FIG. 3 is a circuit diagram of an exemplary SRAM cell 50, which can be implemented as a memory cell BC in FIG. 2 and further implemented in the semiconductor device 10 in FIG. 1. In the illustrated embodiment, the SRAM cell 50 is a single-port (SP) six-transistor (6T) SRAM cell. In various embodiments, the SRAM cell 50 may be other types of memory cells, such as dual-port memory cell or a memory cell having more than six transistors. FIG. 3 has been simplified for the sake of clarity to better understand the inventive concepts of the present disclosure. Additional features can be added in single-port SRAM cell 50, and some of the features described below can be replaced, modified, or eliminated in other embodiments of single-port SRAM cell 50.

The exemplary SRAM cell 50 is a single port SRAM cell that includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 50, which includes a cross-coupled pair of inverters, an inverter 52 and an inverter 54. The inverter 52 includes the pull-up transistor PU-1 and the pull-down transistor PD-1, and the inverter 54 includes the pull-up transistor PU-2 and the pull-down transistor PD-2. In some implementations, the pull-up transistors PU-1, PU-2 are configured as p-type FinFET transistors or p-type GAA transistors, and the pull-down transistors PD-1, PD-2 are configured as n-type FinFET transistors or n-type GAA transistors.

A gate of the pull-up transistor PU-1 interposes a source (electrically coupled with a power supply voltage (VDD)) and a first common drain (CD1), and a gate of pull-down transistor PD-1 interposes a source (electrically coupled with a power supply voltage (VSS), which may be an electric ground) and the first common drain. A gate of pull-up transistor PU-2 interposes a source (electrically coupled with the power supply voltage (VDD)) and a second common drain (CD2), and a gate of pull-down transistor PD-2 interposes a source (electrically coupled with the power supply voltage (VSS)) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

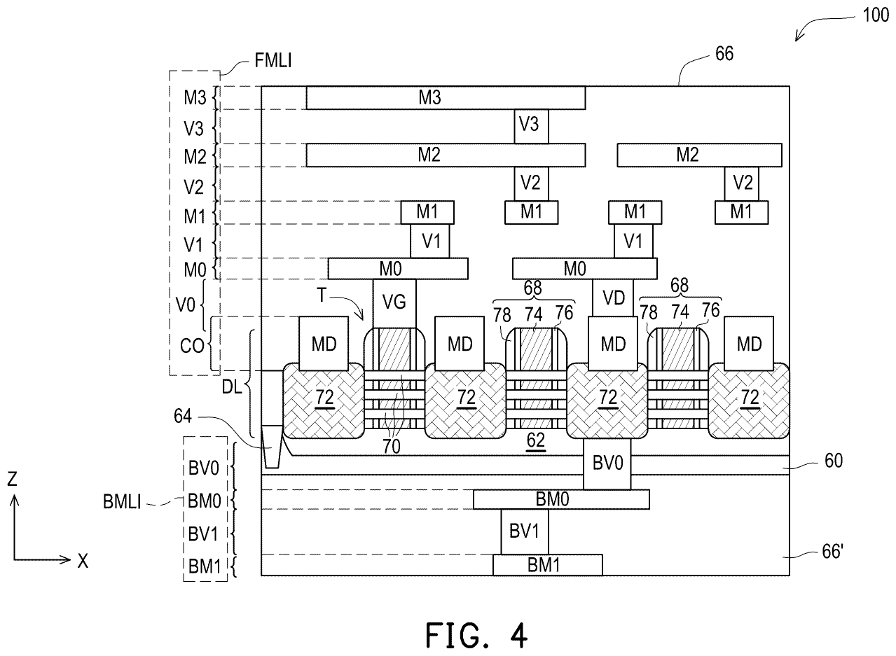

FIG. 4 is a fragmentary diagrammatic cross-sectional view of a semiconductor device 100 including various layers (levels) that can be fabricated over a semiconductor substrate (or wafer) 60 to form a portion of a memory, such as the memory macro 30 of FIG. 2, and/or a portion of an SRAM cell, such as the SRAM cell 50 of FIG. 3, according to various aspects of the present disclosure. As represented in FIG. 4, the various layers include a device layer DL, a frontside multilayer interconnect structure (FMLI) disposed over the device layer DL, and a backside multilayer interconnect structure (BMLI) disposed under the device layer DL. Device layer DL includes devices (e.g., transistors, resistors, capacitors, and/or inductors) and/or device components (e.g., doped wells, gate structures, and/or source/drain features). In some embodiments, device layer DL includes substrate 60, doped regions 62 disposed in substrate 60 (e.g., n-wells and/or p-wells), isolation features 64, and transistors T. In the depicted embodiment, transistors T include suspended channel layers 70 and gate structures 68 disposed between source/drain features 72, where gate structures 68 wrap and/or surround suspended channel layers 70. Each gate structure 68 has a metal gate stack formed from a gate electrode 74 disposed over a gate dielectric 76 and gate spacers 78 disposed along sidewalls of the metal gate stack.

Multilayer interconnect structures FMLI and BMLI electrically couple various devices and/or components of device layer DL, such that the various devices and/or components can operate as specified by design requirements for the memory device. Each of the multilayer interconnect structures FMLI and BMLI may include one or more interconnect layers.

In the depicted embodiment, the FMLI includes a contact layer (CO level), a via zero layer (V0 level), a metal zero layer (M0 level), a via one layer (V1 level), a metal one layer (M1 level), a via two layer (V2 level), a metal two layer (M2 level), a via three layer (V3 level), and a metal three layer (M3 level). The present disclosure contemplates an FMLI having more or less layers and/or levels, for example, a total number of 2 to 10 metal layers (levels) of the FMLI. Each level of the FMLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of the FMLI, such as M0 level, are formed simultaneously. In some embodiments, conductive features at a same level of the FMLI have top surfaces that are substantially planar with one another and/or bottom surfaces that are substantially planar with one another. The CO level includes source/drain contacts (MD) disposed in a dielectric layer 66; the V0 level includes gate vias VG, source/drain contact vias VD, and butted contacts disposed in the dielectric layer 66. The M0 level includes M0 metal lines disposed in dielectric layer 66, where gate vias VG connect gate structures to M0 metal lines, source/drain vias V0 connect source/drains to M0 metal lines, and butted contacts connect gate structures and source/drains together and to M0 metal lines. The V1 level includes V1 vias disposed in the dielectric layer 66, where V1 vias connect M0 metal lines to M1 metal lines. The M1 level includes M1 metal lines disposed in the dielectric layer 66. The V2 level includes V2 vias disposed in the dielectric layer 66, where V2 vias connect M1 lines to M2 lines. The M2 level includes M2 metal lines disposed in the dielectric layer 66. The V3 level includes V3 vias disposed in the dielectric layer 66, where V3 vias connect M2 lines to M3 lines.

In the depicted embodiment, the BMLI includes a backside via zero layer (BV0 level), a backside metal zero layer (BM0 level), a backside via one layer (BV1 level), and a backside metal one layer (BM1 level). The present disclosure contemplates an BMLI having more or less layers and/or levels, for example, a total number of 2 to 10 metal layers (levels) of the BMLI. Each level of the BMLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of the BMLI, such as BM0 level, are formed simultaneously. In some embodiments, conductive features at a same level of the BMLI have top surfaces that are substantially planar with one another and/or bottom surfaces that are substantially planar with one another. The BV0 level includes vias BV0 formed under the device layer DL. For example, the vias BV0 may include one or more backside source/drain vias formed directly under the source/drain feature(s) 72 of the device layer DL and coupled to those source/drain feature(s) 72 by way of a silicide layer. The vias BV0 may include one or more backside gate vias formed directly under and in direct contact with the gate structure(s) 68 of the device layer DL. The BM0 level includes BM0 metal lines formed under the BV0 level and disposed in the backside dielectric structure 66′. The backside gate vias connect gate structures 68 to BM0 metal lines, and the backside source/drain vias connect source/drain features 72 to BM0 metal lines. The BV1 level includes BV1 vias disposed in the backside dielectric structure 66′, where BV1 vias connect BM0 metal lines to BM1 metal lines. The BM1 level includes BM1 metal lines formed under the BV1 level.

FIG. 4 has been simplified for the sake of clarity to better understand the inventive concepts of the present disclosure. Additional features can be added in the various layers of the memory, and some of the features described can be replaced, modified, or eliminated in other embodiments of the memory. FIG. 4 is merely an example and may not reflect an actual cross-sectional view of the memory macro 30 and/or the SRAM cells 50 that is discussed in further detail below.

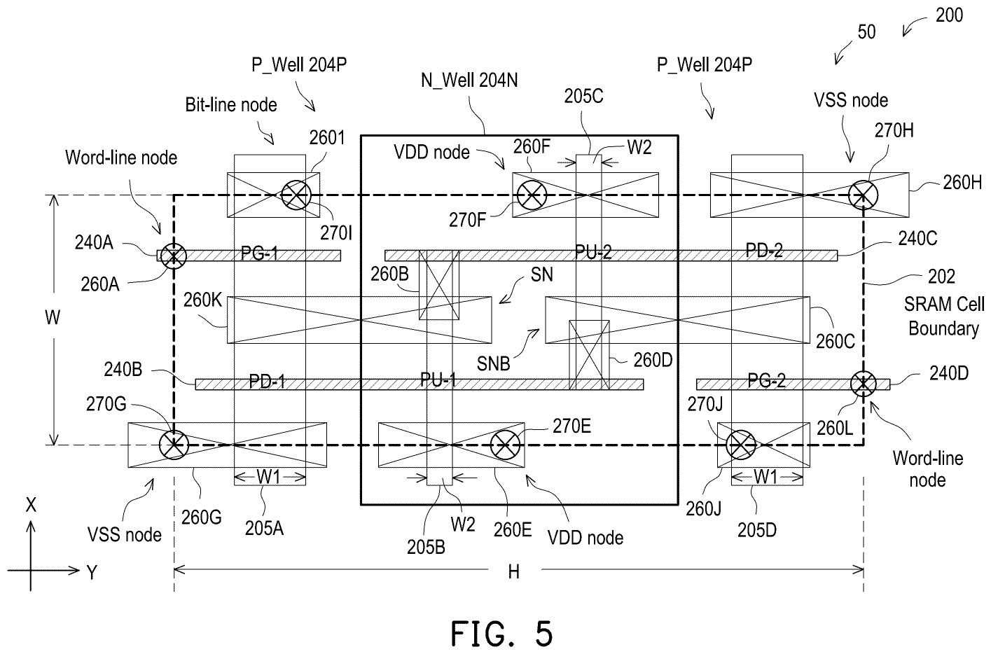

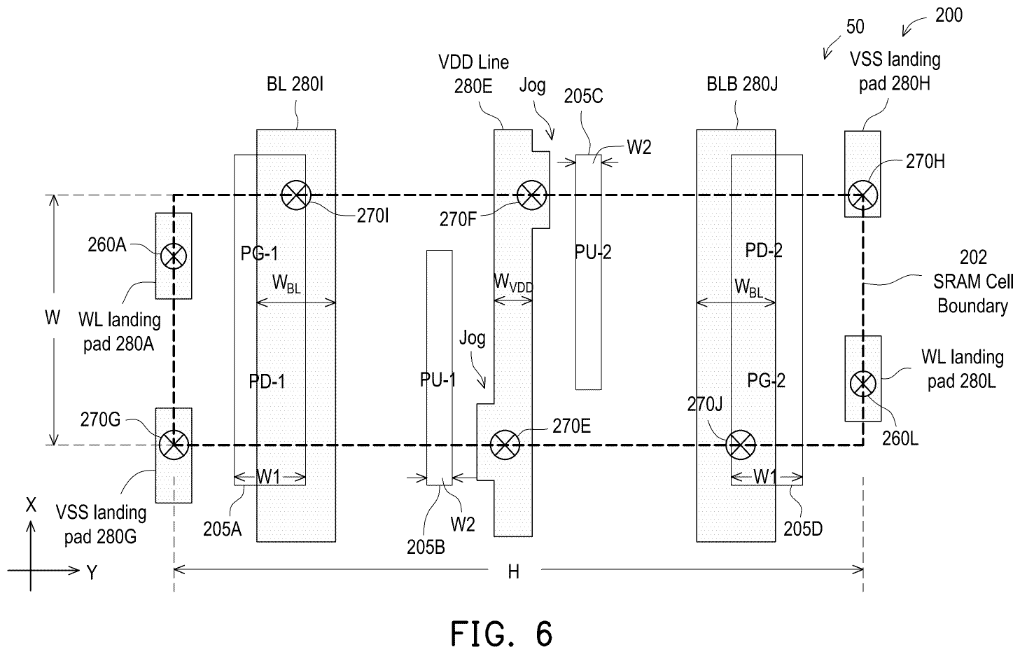

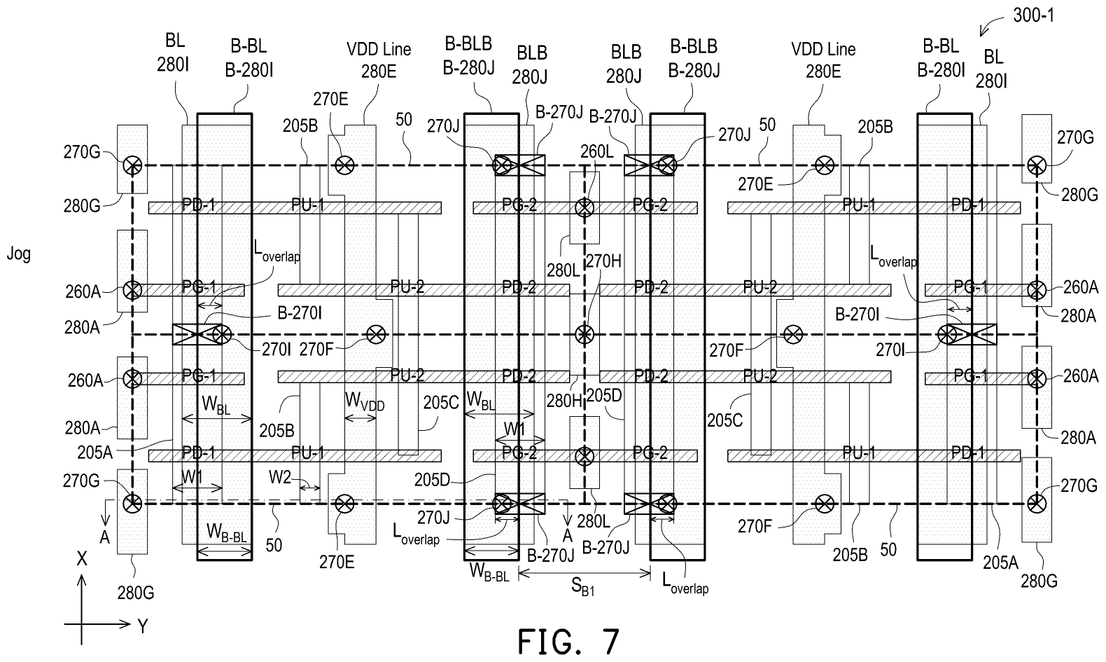

FIGS. 5 and 6 illustrate an exemplary layout 200 of the SRAM cell 50 as in FIG. 3, in which FIG. 5 illustrates the DL level, CO level, and V0 level of the layout 200 and FIG. 6 illustrates V0 level and M0 level of the layout 200. For convenience of illustrating positional relationships, active regions (such as active regions 205A, 205B, 205C, and 205D) as shown in FIG. 5 are also shown in FIG. 6. The SRAM cell 50 has a cell boundary 202 represented by dotted lines in FIGS. 5 and 6. The cell boundary 202 is a rectangular box that is longer in the Y-direction than in the X-direction, for example, about 3.5 times to about 6 times longer. The first dimension of the cell boundary 202 along the X-direction is denoted as a cell width W, and the second dimension of the cell boundary 202 along the Y-direction is denoted as a cell height H. Where the SRAM cell 50 is repeated in a memory array (as shown in FIG. 7), the cell width W may represent and be referred to as a memory cell pitch in the memory array along the X-direction, and the cell height H may represent and be referred to as a memory cell pitch in the memory array along the Y-direction. In the illustrated embodiment, the cell width W is two times a poly pitch. A poly pitch refers to a minimum center-to-center distance between two adjacent gate structures along the X-direction.

The SRAM cell 50 includes active regions 205 (including 205A, 205B, 205C, and 205D) that are oriented lengthwise along the X-direction, and gate structures 240 (including 240A, 240B, 240C and 240D) that are oriented lengthwise along the Y-direction perpendicular to the X-direction. The active regions 205B and 205C are disposed over an n-type well (or n-well) 204N. The active regions 205A and 205D are disposed over p-type wells (or p-wells) 204P that are on both sides of the n-well 204N along the Y-direction. The gate structures 240 engage the channel regions of the respective active regions 205 to form transistors. In that regard, the gate structure 240A engages the channel region of the active region 205A to form an n-type transistor as the pass-gate transistor PG-1; the gate structure 240B engages the channel region of the active region 205A to form an n-type transistor as the pull-down transistor PD-1 and engages the channel region of the active region 205B to form a p-type transistor as the pull-up transistor PU-1; the gate structure 240C engages the channel region of the active region 205D to form an n-type transistor as the pull-down transistor PD-2 and engages the channel region of the active region 205C to form a p-type transistor as the pull-up transistor PU-2; and the gate structure 240D engages the channel region of the active region 205D to form an n-type transistor as the pass-gate transistor PG-2. In the present embodiment, each of the channel regions is in the form of vertically-stacked nanostructures and each of the transistors PU-1, PU-2, PD-1, PD-2, PG-1, and PG-2 is a GAA transistor. Alternatively, each of the channel regions is in the form of a fin and each of the transistors PU-1, PU-2, PD-1, PD-2, PG-1, and PG-2 is a FinFET transistor.

Different active regions in different transistors of the SRAM cell 50 may have different widths (e.g., dimensions measured in the Y-direction) in order to optimize device performance. In more detail, the active region 205A of the pull-down transistor PD-1 and the pass-gate transistor PG-1 has a width W1, the active region 205B of the pull-up transistor PU-1 has a width W2, the active region 205C of the pull-up transistor PU-2 has a width W2, and the active region 205D of the pass-gate PG-2 and the pull-down transistor PD-2 has a width W1. The widths W1 and W2 may also be measured in portions of the active regions corresponding to the channel regions. In other words, these portions of the active regions (from which the widths W1 and W2 are measured) are the channel regions (e.g., the vertically-stacked nanostructures of GAA devices) of the transistors. To optimize SRAM performance, in some embodiments, the width W1 is configured to be greater than the width W2 (W1>W2), as an effort to balance the speed among the n-type transistors and the p-type transistors. In some embodiments, a ratio of W1/W2 may range from about 1.1 to about 3.

The width W1 being larger than the width W2 increases strength of the n-type transistors in the SRAM cell 50, which leads to higher current handling capability of the SRAM cell 50. Such configuration of active regions is suitable for high-current applications (such SRAM cell is referred to as high-current SRAM cell). In some other embodiments, the widths W1 and W2 may be the same (W1=W2). The reduced width W1 allows the SRAM cell 50 to have a smaller cell height H. Such configuration of active regions is suitable for high-density applications (such SRAM cell is referred to as high-density SRAM cell). Taking the macro 20 in FIG. 1 as an example, in one embodiment, the memory macro 20 may include memory arrays 24 all made of high-current SRAM cells; in another embodiment, the memory macro 20 may include memory arrays 24 all made of high-density SRAM cells; and yet in another embodiment, the memory macro 20 may include some memory arrays 24 made of high-current SRAM cells and some other memory arrays 24 made of high-density SRAM cells.

The SRAM cell 50 further includes conductive features in the CO level, V0 level, M0 level, and even higher metal levels (e.g., M1 level, M2 level, etc.). A gate contact 260A electrically connects a gate of the pass-gate transistor PG-1 (formed by gate structure 240A) to a first word line WL landing pad 280A. The first WL landing pad 280A is electrically coupled to a word line WL located at a higher metal level. A gate contact 260L electrically connects a gate of the pass-gate transistor PG-2 (formed by gate structure 240D) to a second word line WL landing pad 280L. The second WL landing pad 280L is electrically coupled to a word line WL located at a higher metal level. A source/drain (S/D) contact 260K electrically connects a drain region of the pull-down transistor PD-1 (formed on the active region 205A (which may include n-type epitaxial source/drain features)) and a drain region of the pull-up transistor PU-1 (formed on the active region 205B (which may include p-type epitaxial source/drain features)), such that a common drain of pull-down transistor PD-1 and pull-up transistor PU-1 form a storage node SN. A gate contact 260B electrically connects a gate of the pull-up transistor PU-2 (formed by gate structure 240C) and a gate of the pull-down transistor PD-2 (also formed by gate structure 240C) to the storage node SN. The gate contact 260B may be a butted contact abutting the S/D contact 260K. An S/D contact 260C electrically connects a drain region of the pull-down transistor PD-2 (formed on the active region 205D (which may include n-type epitaxial source/drain features)) and a drain region of the pull-up transistor PU-2 (formed on the active region 205C (which may include p-type epitaxial source/drain features)), such that a common drain of pull-down transistor PD-2 and pull-up transistor PU-2 form a complementary storage node SNB. A gate contact 260D electrically connects a gate of the pull-up transistor PU-1 (formed by the gate structure 240B) and a gate of the pull-down transistor PD-1 (also formed by the gate structure 240B) to the complementary storage node SNB. The gate contact 260D may be a butted contact abutting the S/D contact 260C.

An S/D contact 260E and an S/D contact via 270E landing thereon electrically connect a source region of pull-up transistor PU-1 (formed on the active region 205B (which can include p-type epitaxial source/drain features)) to a VDD line 280E. The VDD line 280E is electrically coupled to a power supply voltage VDD. An S/D contact 260F and an S/D contact via 270F landing thereon electrically connect a source region of the pull-up transistor PU-2 (formed on the active region 205C (which may include p-type epitaxial source/drain features)) to the VDD line 280E. An S/D contact 260G and an S/D contact via 270G landing thereon electrically connect a source region of the pull-down transistor PD-1 (formed on the active region 205A (which may include n-type epitaxial source/drain features)) to a first VSS landing pad 280G. The first VSS landing pad 280G is electrically coupled to an electric ground VSS. An S/D contact 260H and an S/D contact via 270H landing thereon electrically connect a source region of the pull-down transistor PD-2 (formed on the active region 205D (which may include n-type epitaxial source/drain features)) to a second VSS landing pad 280H. The second VSS landing pad 280H is electrically coupled to an electric ground VSS. The S/D contact 260G and the S/D contact 260H may be device-level contacts that are shared by adjacent SRAM cells 50 (e.g., four SRAM cells 50 abutting at a same corner may share one S/D contact 260H). An S/D contact 2601 and an S/D contact via 270I landing thereon electrically connect a source region of the pass-gate transistor PG-1 (formed on the active region 205A (which may include n-type epitaxial source/drain features)) to a bit line BL 280I. An S/D contact 260J and an S/D contact via 270J landing thereon electrically connect a source region of the pass-gate transistor PG-2 (formed on the active region 205D (which may include n-type epitaxial source/drain features)) to a complementary bit line (bit line bar) BLB 280J.

Conductive features in the CO level, M0 level, and higher metal levels (e.g., M1 level, M2 layer, etc) are routed along a first routing direction or a second routing direction that is different than the first routing direction. For example, the first routing direction is the X-direction (and substantially parallel with the lengthwise direction of active regions 205A-205D) and the second routing direction is the Y-direction (and substantially parallel with the lengthwise direction of gate structures 240A-240D). In the depicted embodiment, source/drain contacts (260C, 260E, 260F, 260G, 260H, 2601, 260J, 260K) have longitudinal (lengthwise) directions substantially along the Y-direction (i.e., second routing direction), and butted contacts (260B, 260D) have longitudinal directions substantially along the X-direction (i.e., first routing direction). Metal lines of even-numbered metal layers (i.e., M0 level and M2 level) are routed along the X-direction (i.e., the first routing direction) and metal lines of odd-numbered metal layers (i.e., M1 level and M3 level) are routed along the Y-direction (i.e., the second routing direction). For example, in the M0 level as shown in FIG. 6, the bit line 280I, bit line bar 280J, VDD line 280E, VSS landing pad 280G, VSS landing pad 280H, word line landing pad 280A, word line landing pad 280L have longitudinal directions substantially along the X-direction. Further, since the metal lines in the same metal level (e.g., the M0 level) have the same longitudinal directions, the metal lines can be positioned in metal tracks arranged in parallel. A metal track may include one or more metal lines. For example, a metal track may include a single metal line that extends through the entire SRAM cell, or a metal track may include one or more local metal lines that do not extend through the entire SRAM cell.

The illustrated metal lines are generally rectangular-shaped (i.e., each has a length greater than its width), but the present disclosure contemplates metal lines having different shapes and/or combinations of shapes to optimize and/or improve performance (e.g., reduce resistance) and/or layout footprint (e.g., reduce density). For example, the VDD line 280E may optionally have jog portions (or simply as jogs) added as shown in FIG. 6. A jog refers to a junction where two segments of different widths meet each other. The jog portion of the VDD line 280E has a larger width than other portion of the VDD line 280E. The jog may add about 1% to about 50% extra width to the VDD line 280E. The jogs are added to interconnection regions (areas) of the VDD line 280E to increase cross-sectional areas of the interconnection regions. Increasing cross-sectional areas of the interconnection regions of the VDD line 280E allows for increasing cross-sectional areas of the S/D contact vias 270E and 270F in the V0 level, which reduces routing resistance between the connection of the VDD line 280E and respective source/drain contacts (and thus to underlying source/drain regions).

“Landing pad” generally refers to metal lines in metal layers that provide intermediate, local interconnection for the SRAM cell, such as (1) an intermediate, local interconnection between a device-level feature (e.g., gate or source/drain) and a bit line, a bit line bar, a word line, a voltage line or (2) an intermediate, local interconnection between bit lines, word lines, or voltage lines. For example, the VSS landing pad 280G is connected to source/drain contact 260G of the transistor PD-1 and further connected to a VSS line located in a higher metal level, the VSS landing pad 280H is connected to source/drain contact 260H of the transistor PD-2 and further connected to a VSS line located in a higher metal level, the WL landing pad 280A is connected to a gate of the transistor PG-1 and further connected to a word line WL located in a higher metal level, and the WL landing pad 280L is connected to a gate of the transistor PG-2 and further connected to a word line WL located in a higher metal level. Landing pads have longitudinal dimensions that are large enough to provide a sufficient landing area for their overlying vias (and thus minimize overlay issues and provide greater patterning flexibility). In the depicted embodiment, landing pads have longitudinal dimensions that are less than dimensions of the SRAM cell 50, such as dimensions along the X-direction that are less than cell width W and dimensions along the Y-direction that are less than cell height H. As a comparison to the landing pads, the bit line 280I, the bit line bar 280J, and the VDD line 280E have longitudinal dimensions along the X-direction that are greater than cell width W of the SRAM cell 50. As they travel through the entire SRAM cell 50 along the X-direction, the bit line 2801, the bit line bar 280J, and the VDD line 280E at the M0 level are also referred to as global metal lines, while others are referred to as local metal lines (including landing pads). In some embodiments, a length of each of the bit line 280I, the bit line bar 280J, and the VDD line 280E is sufficient to allow electrical connection of multiple SRAM cells in a column (or a row) to the respective global metal line.

The metal lines (global metal lines and local metal lines) in the SRAM cell 50 at the M0 level may have different widths. For example, the main portion of the VDD line 280E has a width W_{VDD}, and the bit line 280I and bit line bar 280J each have a uniform width W_{BL}. In some embodiments, the width W_{BL} is larger than the width W_{VDD} (W_{BL}>W_{VDD}). Having the largest width reserved to the bit line 280I and bit line bar 280J allows the signal lines in the bit line pair to generally benefit from a reduced resistance and thus a reduced voltage drop along the signal lines. In some embodiments, a ratio of width W_{BL} to width W_{VDD} (i.e., W_{BL}/W_{VDD}) is about 1.1 to about 2. In the illustrated embodiment, edges (and centerlines) of the bit line 280I and bit line bar 280J are offset from edges (and centerlines) of the underlying active regions 205A and 205D, respectively. The offsets increase cross-sectional areas of the interconnection regions between the bit line 280I and bit line bar 280J with the respective underneath S/D contact vias 270I and 270J. Still further, the width W_{BL} of the bit line 280I and bit line bar 280J may be larger than the width W1 of the active regions 205A and 205D. In some embodiments, a ratio of width W_{BL} to width W1 (i.e., W_{BL}/W1) is about 1.1 to about 1.5.

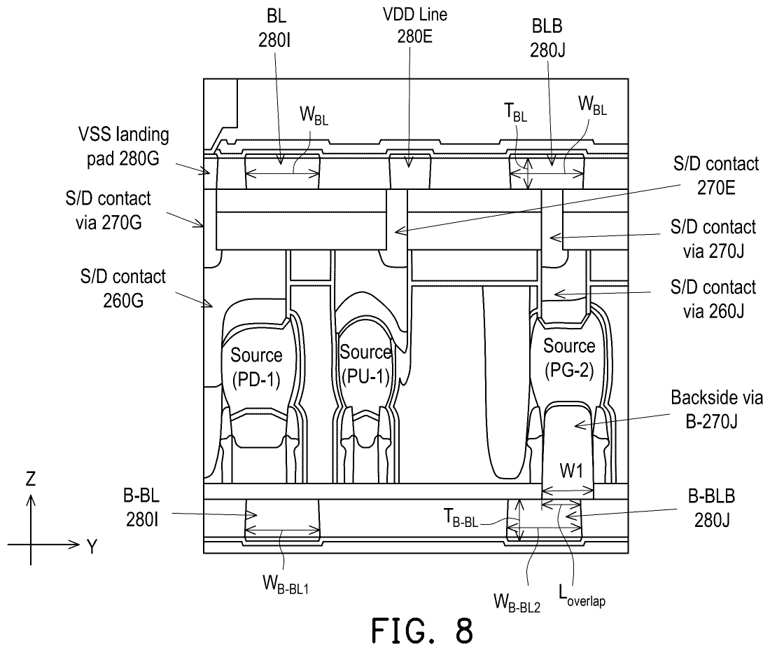

FIG. 7 illustrates a layout 300-1 of various layers of a portion of an SRAM array, such as a portion of the memory array 32 in FIG. 2, according to the present disclosure. Particularly, the layout 300-1 includes active regions and gate structures in the DL level, V0 level and M0 level as a portion of the FMLI of the SRAM array, as well as BV0 level and BM0 level as a portion of the BMLI of the SRAM array. FIG. 7 has been simplified for reasons of visual clarity and to better understand the inventive concepts of the present disclosure. For example, some features including well regions, S/D contacts, and butted contacts are omitted. In the depicted portion of the layout 300-1, four SRAM cells are arranged in the X-direction and the Y-direction, forming a 2×2 sub-array within the SRAM array. Each SRAM cell may use the layout 200 of the SRAM cell 50 as depicted in FIGS. 5 and 6. Two adjacent SRAM cells in the X-direction are line symmetric with respect to a common boundary therebetween, and two adjacent SRAM cells in the Y-direction are line symmetric with respect to a common boundary therebetween. Consistent with the discussion above with reference to FIG. 2, a column is referred to as being in the Y-direction of an array, and a row is referred to as being in the X-direction of an array. FIG. 8 illustrates a cross-sectional view of the SRAM array taken along line A-A in FIG. 7, in accordance with some embodiments of the present disclosure.

As adjacent cells in the array are mirror images along a common boundary between the adjacent cells, some active regions in an SRAM cell may extend through multiple SRAM cells in a row. In FIG. 7, the active region 205A for the transistors PG-1 and PD-1 in one SRAM cell extends into the abutting SRAM cell as the active region for the transistors PD-1 and PG-1 in the abutting SRAM cell. The active region 205C for the transistor PU-2 in one SRAM cell extends into the abutting SRAM cell as the active region for the transistor PU-2 in the abutting SRAM cell. The active region 205D for the transistors PG-2 and PD-2 in one SRAM cell extends into the abutting SRAM cell as the active region for the transistors PD-2 and PG-2 in the abutting SRAM cell. Similarly, some gate structures can be shared by multiple SRAM cells in a column. For example, the gate structure for the transistor PG-1 in one SRAM cell extends into the abutting SRAM cell as the gate structure for the transistor PG-1 in the abutting SRAM cell. The gate structure for the transistor PG-2 in one SRAM cell extends into the abutting SRAM cell as the gate structure for the transistor PG-2 in the abutting SRAM cell. The spacing between active regions along the Y-direction and the spacing between gate structures along the X-direction can be uniform. This configuration can improve the uniformity of an array layout. FIG. 7 also depicts the metal lines at the M0 level, such as the bit line 280I, bit line bar 280J, VDD line 280E as the global metal lines that extends across multiple SRAM in a row, and word line landing pads 280A/280L, VSS landing pads 280G/280H as the local metal lines.

Referring to FIGS. 7 and 8 collectively, in SRAM device design, the power rails and signal lines are not necessarily all formed on the frontside of the integrated circuit structure but may be distributed on both the frontside and backside of the integrated circuit structure. For example, the integrated circuit structure may include FMLI and BMLI disposed on the frontside and backside of the integrated circuit structure respectively and configured to connect various components of the pull-up devices, pull-down devices, and pass-gate devices to form the SRAM cells. The configuration is designed with considerations of various factors and parameters, including sizes of various conductive features, packing density, resistance of the conductive features, parasitic capacitances among adjacent conductive features, overlay shifting and processing margins. In the illustrated embodiment, some signal lines, particularly bit line BL and bit line bar (complementary bit line) BLB in the bit line pairs are also formed on the backside of the SRAM array. In the context, the bit line BL and the bit line bar BLB may also be collectively referred to as bit lines if not separately indicated. Thus, the bit lines and bit line bars formed on the frontside of the SRAM array may be collectively referred to as frontside bit lines (BL and BLB), the bit lines formed on the backside of the SRAM array may be collectively referred to as backside bit lines (B-BL and B-BLB), and the frontside and backside bit lines may be collectively referred to as dual side bit lines, or just bit lines. Compared with a frontside bit line alone, the dual side bit lines may reduce the resistance by about 30% to about 50% along the bit line control signal path.

On the backside of the SRAM array, the illustrated portion of the BMLI includes BV0 level and BM0 level. The BV0 level includes backside vias (or referred to as backside source/drain contacts) B-270I and B-270J. The backside vias B-270I and B-270J can be considered as counterparts of the frontside source/drain contacts and contact vias. Similar to functions of the frontside source/drain contacts and contact vias that electrically couple the source regions of the pass-gate transistors PG-1 and PG-2 to the frontside bit line (BL) 280I and the frontside bit line bar (BLB) 280J, respectively, the backside vias B-270I and B-270J electrically couple the source regions of the pass-gate transistors PG-1 and PG-2 to the backside bit line (B-BL) B-280I and the backside bit line bar (B-BLB) B-280J, respectively. The backside vias B-270I and B-270J May have the same dimension along the Y-direction as the active regions 205A and 205D, respectively. This is due to one exemplary backside manufacturing flow in which a backside via is formed by etching a fin-shape base in an active region from the backside to form a backside trench and filling the backside trench with conductive materials. Therefore, the backside vias inherit the width of the active region. In other words, the backside vias B-270I and B-270J each may have the width W1 as the active regions 205A and 205D.

The BM0 level includes backside bit lines B-280I and backside bit line bars B-280J as global metal lines extending lengthwise in the X-direction through the array and shared by multiple SRAM cells in the same row. The backside bit line B-280I is positioned directly under the respective frontside bit line 280I and electrically coupled to the respective frontside bit line 280I through an electrical path including the backside via B-270I, the source/drain feature of the pass-gate transistor PG-1, the source/drain contact 260I, and the source/drain contact via 270I. Similarly, the backside bit line bar B-280J is positioned directly under the respective frontside bit line bar 280J and electrically coupled to the respective frontside bit line bar 280J through an electrical path including the backside via B-270J, the source/drain feature of the pass-gate transistor PG-2, the source/drain contact 260J, and the source/drain contact via 270J.

The backside bit line B-280I and backside bit line bar B-280J each have a width W_{B-BL}. Since the thickness of the metal lines formed in the backside manufacturing process is generally larger than the thickness of the metal line formed in the frontside manufacturing process, the width of the backside signal lines can be smaller than the frontside signal lines while maintaining a similar resistance due to the larger thickness. As shown in FIG. 8, the thickness T_{B-BL} of the backside bit line B-280I and backside bit line bar B-280J is larger than or equal to the thickness T_{BL} of the frontside bit line 280I and bit line bar 280J (T_{B-BL}≥T_{BL}), and the width W_{B-BL} is less than or equal to the width W_{BL} (W_{B-BL}≤W_{BL}). In some embodiments, a ratio of width W_{B-BL} to width W_{BL} (i.e., W_{B-BL}/W_{BL}) is about 0.2 to about 1 (0.2 ≤W_{B-BL}/W_{BL}≤1). This range is not arbitrary or trivial. Having narrower backside signal lines helps enlarging a line-to-line spacing (e.g., an increased distance S_{B1} between opposing edges of two adjacent backside bit line bars B-280J in FIG. 7) and consequently reducing a parasitic capacitance between adjacent backside signal lines. Meanwhile, if the ratio is less than about 0.2, the resistance of the backside signal lines may become too large and adversely impact the signal swing headroom due to larger voltage drop along the signal lines.

To further enlarge a separation between adjacent backside signal lines as an effort to further reduce parasitic capacitance, the backside signal lines may just partially overlap with the respective backside via to spare more line-to-line spacing. That is, the overlapping length Lₒᵥₑᵣₗₐₚ may be smaller than a length of the backside via W1 (Lₒᵥₑᵣₗₐₚ<W1). For example, as shown in FIGS. 7 and 8, a centerline of the backside bit line B-280I may be offset from a centerline of the respective active region 205A and thus offset from a centerline of the backside via B-270I, resulting in a partial overlapping between the backside bit line B-280I and the backside via B-270I. The edges of the backside bit line B-280I may also be offset from the edges of the respective active region 205A. One edge of the backside bit line B-280I may be aligned with a respective edge of the frontside bit line 280I in a top view as illustrated in FIG. 7. In some embodiments, both edges of the backside bit line B-280I may be aligned with both edges of the frontside bit line 280I (thus W_{B-BL}=W_{BL}). Alternatively, both edges of the backside bit line B-280I may also be offset from both edges of the frontside bit line 280I. Similarly, a centerline of the backside bit line bar B-280J may be offset from a centerline of the respective active region 205D and thus offset from a centerline of the backside via B-270J, resulting in a partial overlapping between the backside bit line bar B-280J and the backside via B-270J. The edges of the backside bit line bar B-280I may also be offset from the edges of the respective active region 205D. One edge of the backside bit line bar B-280J may be aligned with a respective edge of the frontside bit line bar 280J in a top view as illustrated in FIG. 7. In some embodiments, both edges of the backside bit line bar B-280J may be aligned with both edges of the frontside bit line bar 280J (thus W_{B-BL}=W_{BL}). Alternatively, both edges of the backside bit line bar B-280J may also be offset from both edges of the frontside bit line bar 280J. In some embodiments, a ratio of the overlapping length Loverlap to a length of the backside via (also a length of the respective active region in the illustrated embodiment) W1 is about 0.3 to about 1 (0.3<Lₒᵥₑᵣₗₐₚ/W1<1). This range is not arbitrary or trivial. Having a ratio equal to or larger than 1 may reduce line-to-line spacing between adjacent backside signal lines and consequently enlarge a parasitic capacitance. Meanwhile, if the ratio is less than 0.3, the contact resistance between the backside signal lines and backside vias may become too large and adversely impact the signal swing headroom due to larger voltage drop along the signal lines. In some embodiments, a ratio of width W_{B-BL} to width W1 is about 0.3 to about 2 (0.3<W_{B-BL}/W1<2). This range is not arbitrary or trivial. Having the ratio in this range keeps a balance between the active region widths for current driving capability in high performance and/or high current transistor designs and the parasitic resistance and capacitance requirements for the backside signal lines.

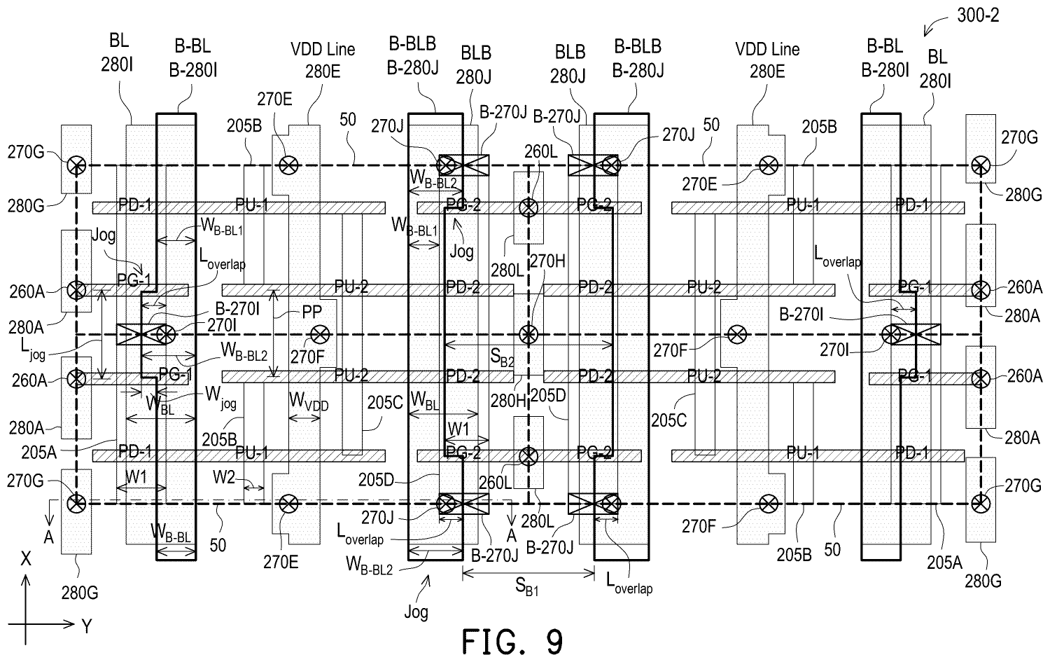

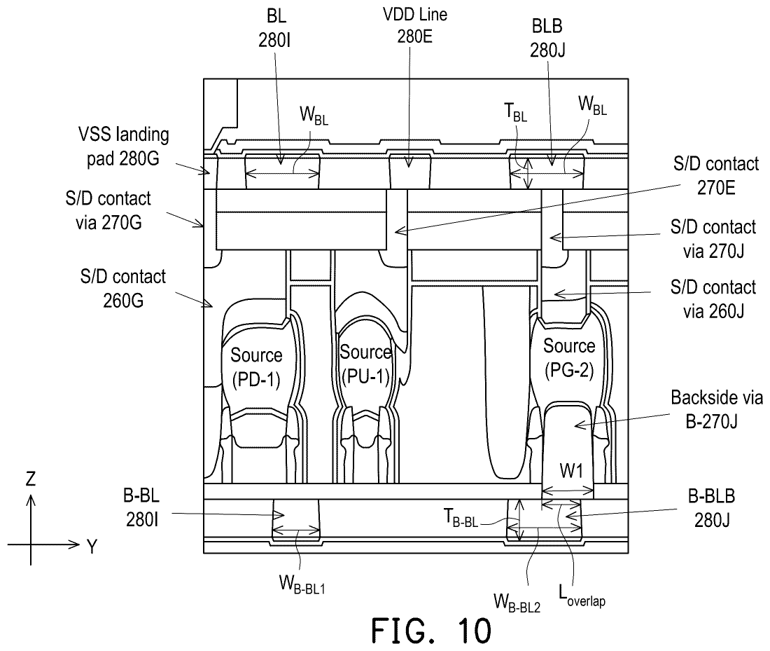

FIG. 9 illustrates an alternative layout 300-2 of various layers of a portion of an SRAM array, and FIG. 10 illustrates a cross-sectional view of the SRAM array taken along line A-A in FIG. 9, in accordance with some embodiments of the present disclosure. The layout 300-2 and its cross-sectional view as depicted in FIGS. 9 and 10 are similar to the layout 300-1 and its cross-sectional view as depicted in FIGS. 7 and 8. However, the layout 300-2 provides an increased line-to-line spacing in the backside signal lines, which leads to a reduce parasitic capacitance.

One difference between the layouts 300-1 and 300-2 is that shapes of the backside bit line B-280I and the backside bit line bar B-280J as depicted in FIG. 9 are different from those as depicted in FIG. 7. More specifically, other than having a rectangular shape with a uniform width W_{B-BL}, the backside bit line B-280I and the backside bit line bar B-280J as depicted in FIG. 9 have a non-uniform width. The backside bit line B-280I and the backside bit line bar B-280J as depicted in FIG. 9 each include a main portion extending lengthwise along the X-direction with a width W_{B-BL1} and jog portions protruding from the main portion along the Y-direction. The jog itself has a width W_{jog} measured along the Y-direction and a length L_{jog} measured along the X-direction. That is, the backside bit line B-280I and the backside bit line bar B-280J have a width W_{B-BL2} measured at the jogs as W_{B-BL2}=W_{B-BL1}+W_{jog}. The jog portions provide sufficient contact area between the backside signal lines and the backside vias, allowing the main portion of the backside signal lines to shrink and thus increasing the line-to-line spacing from S_{B1} to S_{B2} by two extra jog widths (i.e., S_{B2}=S_{B1}+2×W_{jog}).

In the illustrated embodiment, the length L_{jog} of the jogs equals to the poly pitch. In the illustrated embodiment, the gate structures are evenly distributed along the X-direction with a uniform distance between two adjacent gate structures. The uniform distance is denoted as a gate pitch or a poly pitch (“PP”). In various embodiments, a ratio of the length L_{jog} of the jogs to the poly pitch is about 0.5 to about 1.5 (0.5<L_{jog}/PP<1.5). In various embodiments, a ratio of the width W_{jog} of the jogs to the width W_{B-BL2} measured at the jog portions is about 0.3 to about 0.7 (0.3≤W_{jog}/W_{B-BL2}≤0.7). This range is not arbitrary or trivial. Having the ratio in this range keeps a balance between the parasitic resistance and capacitance requirements for the backside signal lines and improves device performances. In some embodiments, a ratio of the width W_{B-BL1} to the width W1 of the active region 205A is about 0.3 to about 2 (0.3<W_{B-BL1}/W1<2). This range is not arbitrary or trivial. Having the ratio in this range keeps a balance between the active region widths for current driving capability in high performance and/or high current transistor designs and the parasitic resistance and capacitance requirements for the backside signal lines.

One difference between the cross-sectional views as depicted in FIGS. 8 and 10 is that the backside bit line B-280I and the backside bit line bar B-280J have the same width W_{B-BL} as depicted in FIG. 8, but different widths W_{B-BL1} and W_{B-BL2}, respectively, as depicted in FIG. 10. This difference arises because the cross-sectional view along line A-A in FIG. 10 cuts through the main portion of the backside bit line B-280I, which has a smaller width W_{B-BL1}, and the jog portion of the backside bit line bar B-280J, which has a larger width W_{B-BL2}.

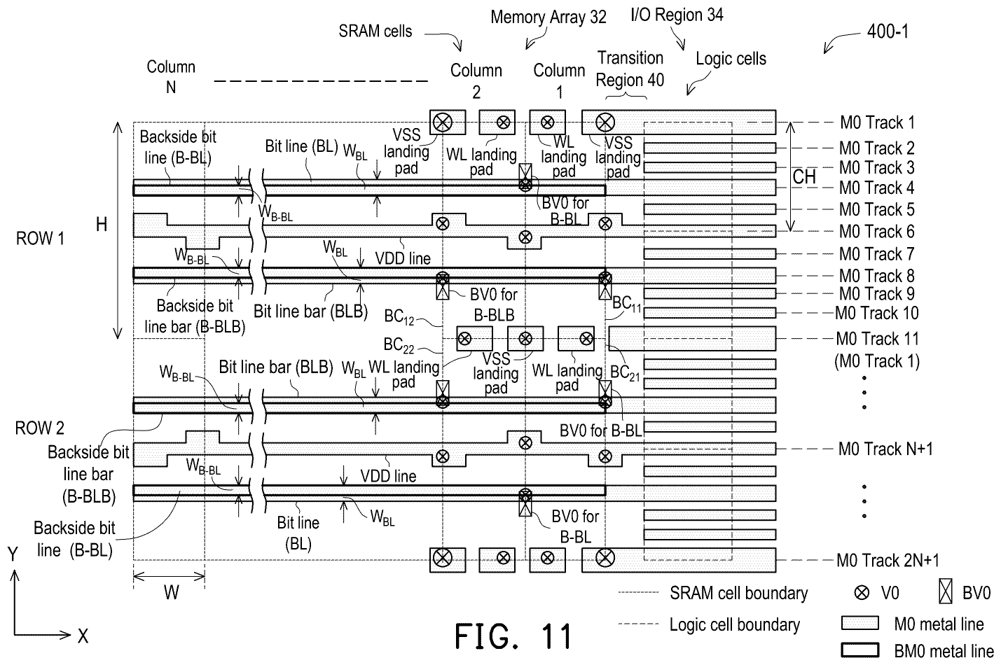

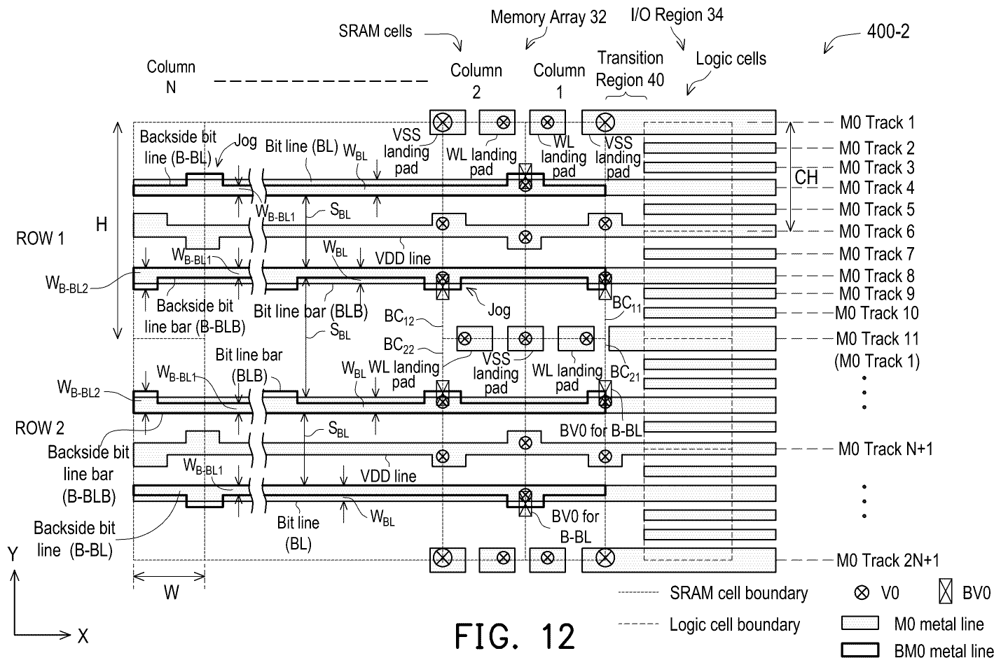

Reference is now made to FIGS. 11 and 12 collectively. FIG. 11 illustrates M0 level and BM0 level of a layout 400-1 of a portion of the memory macro 30 (FIG. 2), which includes first two rows (Rows 1-2) of the memory array 32 and a portion of the logic cells in the I/O circuit (or referred to as I/O region) 34. FIG. 11 has been simplified for the sake of clarity to better understand the inventive concepts of the present disclosure. For example, some features including well regions, active regions, gate structures, S/D contacts, butted contacts, and vias are omitted in FIG. 11. Meanwhile, some vias at V0 level and backside vias at BV0 level in the SRAM cells of the first two columns and first two rows (i.e., BC₁₁, BC₁₂, BC₂₁, BC₂₂) of the memory array 32 are shown for better illustrating the embodiments. FIG. 12 illustrates an alternative layout 400-2, in accordance with some embodiments of the present disclosure. The layouts 400-1 and 400-2 represented in FIGS. 11 and 12 are similar. One difference is that the backside signal lines represented in FIG. 11 adopt the uniform width (W_{B-BL}) as illustrated in FIG. 7 and the backside signal lines represented in FIG. 12 adopt the non-uniform width (W_{B-BL1} and W_{B-BL2}) with jog portions as illustrated in FIG. 9.

As discussed above, gate structures intersect respective active regions in forming transistors. Transistors formed at the intersections of the active regions and the gate structures within the memory array 32 are devoted to form SRAM cells. The transistors formed at the intersections of the active regions and the gate structures within the I/O region 34 are devoted to form logic cells. In the illustrated embodiment, the transistors in the SRAM array 32 form a plurality of SRAM cells, such as SRAM cells BC₁₁, BC₁₂, BC₂₁, BC₂₂ (collectively, SRAM cells BC). Each SRAM cell in the array may use the layout 200 of the SRAM cell 50 as depicted in FIG. 5. In some embodiments, two adjacent SRAM cells in the X-direction are line symmetric with respect to a common boundary therebetween, and two adjacent SRAM cells in the Y-direction are line symmetric with respect to a common boundary therebetween. That is, the 2×2 sub-array formed by the four SRAM cells may use the layout 300 as depicted in FIG. 7 or FIG. 9. Particularly, the SRAM cell BC₁₂ is a duplicate cell for the SRAM cell BC₁₁ but flipped over the Y-axis; the SRAM cell BC₂₂ is a duplicate cell for the SRAM cell BC₁₂ but flipped over the X-axis; and the SRAM cell BC₂₁ is a duplicate cell for the SRAM cell BC₁₁ but flipped over the X-axis.

In the illustrated embodiment, the transistors in the I/O region 34 form a plurality of logic cells. The logic cells may be standard cells, such as inventor (INV), AND, OR, NAND, NOR, Flip-flip, SCAN and so on. The logic cells implement various logic functions to the SRAM cells BC. The logic functions of the logic cells include, for example, write and/or read decoding, word line selecting, bit line selecting, data driving and memory self-testing. As depicted, each logic cell has a logic cell height CH, which is half of the SRAM cell height H (H=2×CH). Therefore, two logic cells have a boundary with opposing edges aligned with opposing edges of the boundary of one SRAM cell with the edges spaced in the Y-direction and each edge extending in the X-direction.

Between the opposing boundary lines of the SRAM cells in the memory array 32 and the logic cells in the I/O region 34 is an active region transition region 40, or simply as the transition region. The transition region 40 provides isolation between the transistors formed in the memory array 32 and the transistors formed in the I/O region 34. Metal lines in FMLI and/or BMLI extend across the transition region 40 to provide electrical connection between the memory array 32 and the I/O region 34.

In the illustrated embodiment, the I/O region 34 at M0 level includes a plurality of metal tracks arranged in parallel. Particularly, in the layout 400-1 or 400-2, two abutting logic cells include eleven metal tracks arranged in order from first (M0 Track 1) to eleventh (M0 Track 11) along the Y-direction. The center lines of the metal tracks are represented by the horizontal dashed lines.

The metal lines at M0 level in the SRAM cells are aligned with the metal tracks in the I/O region 34, allowing the metal lines in the logic cells to extend into the SRAM cells. Thus, there is no need for edge cells between the SRAM cells and the logic cells to provide metal transitions. In the M0 Track 1, a VSS line extends into the SRAM cell BC₁₁ and merges with the VSS landing pad. In the M0 Track 2, the metal line as a signal line in the logic cell remains in the boundary of the respective logic cell. In the M0 Track 3, the metal line as a signal line in the logic cell remains in the boundary of the respective logic cell. In the M0 Track 4, the metal line as the bit line BL in the logic cell also extends into and through the SRAM cells as a bit line BL for multiple SRAM cells in the same row. In the M0 Track 5, the metal line as a signal line in the logic cell remains in the boundary of the respective logic cell. In the M0 Track 6, the metal line as a VDD line in the logic cell also extends into and through the SRAM cells as a VDD line for multiple SRAM cells in the same row. In the M0 Track 7, the metal line as a signal line in the logic cell remains in the boundary of the respective logic cell. In the M0 Track 8, the metal line as the bit line bar BLB in the logic cell also extends into and through the SRAM cells as a bit line bar BLB for multiple SRAM cells in the same row. In the M0 Track 9, the metal line as a signal line in the logic cell remains in the boundary of the respective logic cell. In the M0 Track 10, the metal line as a signal line in the logic cell remains in the boundary of the respective logic cell. In the M0 Track 11, the metal line as a VSS line in the logic cell may extend through the boundary of the respective logic cell but does not contact the word line WL landing pad.

The boundary of an SRAM cell may abut the boundary of one or two logic cells. The one or two logic cells provide 2*N+1 metal tracks, where N is an integer. The metal line in the center metal track (the (N+1)^{th} metal track) extends into the SRAM cell as a common VDD line for both the SRAM cell and the one or two logic cells. The two metal lines in the two metal tracks in equal spacing from the center metal track extend into the SRAM cell as a bit line BL and a bit line bar BLB, respectively, for both the SRAM cell and the one or two logic cells. The two metal lines in the first and the (2*N+1)^{th} metal tracks extend through the boundary of the one or two logic cells and connect to one of the VSS landing pads in the SRAM cell.

In the illustrated embodiment, the metal lines in the metal tracks 4 and 8 extend from the logic cells and through the SRAM cells in the same row as a bit line BL and a bit line bar BLB, respectively. Alternatively, depending on the layout, it may be the metal lines in the metal tracks 2 and 10, or the metal tracks 3 and 9, or the metal tracks 5 and 7 that extend from the logic cells and through the SRAM cells as a bit line BL and a bit line bar BLB, respectively. Each of the bit lines BL has its counterpart backside bit line B-BL on the backside of the memory array 32, and each of the bit line bars BLB has its counterpart backside bit line bar B-BLB on the backside of the memory array 32. As discussed above, in the context, the bit line BL and the bit line bar BLB may also be collectively referred to as frontside bit lines if not separately indicated, and the backside bit line B-BL and the backside bit line bar B-BLB may also be collectively referred to as backside bit lines if not separately indicated.

In the layouts 400-1 and 400-2, the frontside bit lines (BL, BLB) and the backside bit lines (B-BL, B-BLB) each extend through the SRAM cells in the same row from Column 1 to Column N and electrically couple the SRAM cells in the same row to the same bit line control signal. By having the backside bit lines in parallel with the respective frontside bit lines, resistivity along the bit line control signal path is reduced, such as by about 30% to about 50%, in some embodiments. In FIG. 11, each frontside bit line (BL or BLB) has a uniform width W_{BL}, and each backside bit line (B-BL or B-BLB) has a uniform width W_{B-BL}. In FIG. 12, each frontside bit line (BL or BLB) has a uniform width W_{BL}, and each backside bit line (B-BL or B-BLB) has a non-uniform width with a smaller width W_{B-BL1} for its main portion and a larger width W_{B-BL2} for its jog portions. Edge-to-edge spacing S_{BL} (SB₂ in FIG. 9) between two adjacent backside bit lines may be uniform. Since within two abutting SRAM cells (each with a cell height H) there are four backside bit lines spaced apart along the Y-direction each with a width W_{B-BL1}, the edge-to-edge spacing S_{BL} can be expressed as S_{BL}=(2×H−4×W_{B-BL1})/4.

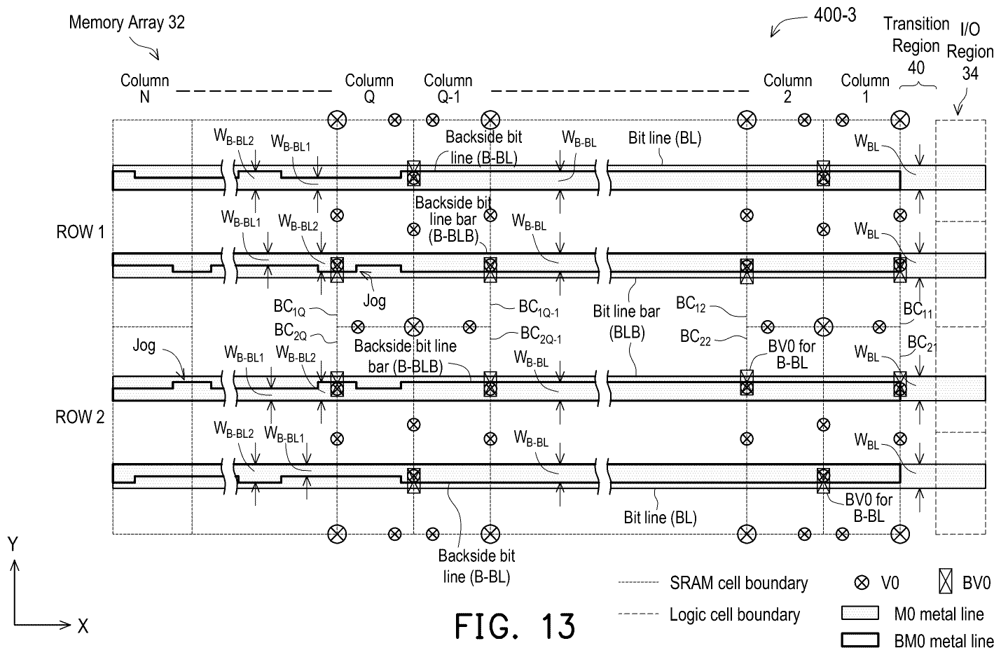

Reference is now made to FIGS. 13, which illustrates an alternative layout 400-3 of a portion of the memory macro 30 (FIG. 2). In the layouts 400-1 and 400-2, the SRAM cells in different locations of the SRAM array 32 are fed by the backside bit lines of the same geometries together with the frontside bit lines. In some applications, preferences for resistivity of the bit line control signal path may vary depending on whether the SRAM cells are located close to the I/O periphery or at a distance from the I/O periphery. For SRAM cells in the columns far away from the I/O periphery, higher resistivity along the bit line control signal path and accordingly narrower bit lines help achieving reduced parasitic capacitance, thereby enabling faster access times and lower power consumption. In contrast, for SRAM cells in the columns close to the I/O periphery, smaller resistivity along the bit line control signal path and accordingly wider bit lines help achieving reduced resistance, which facilitates maintaining voltage headroom and signal integrity along the bit lines. The alternative layout 400-3 illustrates such an embodiment.

Similar to FIGS. 11 and 12, FIG. 13 illustrates the frontside bit lines (BL, BLB) and backside bit lines (B-BL, B-BLB) in the first two rows (Rows 1-2) of the memory array 32 for simplicity, while numerous other features are omitted. Some vias at V0 level and backside vias at BV0 level in the SRAM cells are shown for better illustrating the embodiments.

In the memory array 32, each of the frontside bit lines (BL or BLB) and the backside bit lines (B-BL or B-BLB) is shared by the memory cells in the same row starting from Column 1 to Column N. State differently, a number of N memory cells in the same row are coupled to (or fed by) the same bit line (either frontside or backside). In some embodiments, N is a power of 2, such as 64, 128, 256, 512, and so on. In furtherance of some embodiments, N is larger than 128 (e.g., N≥256). The present disclosure contemplates N being any other integer.

Each of the frontside bit lines (BL or BLB) is a straight line along the X-direction with a uniform width W_{BL}. Each of the backside bit lines (B-BL or B-BLB) has a first portion (or segment) coupled to the SRAM cells from Column 1 to Column Q-1 and a second portion (or segment) coupled to the SRAM cells from Column Q to Column N. The first portion is a straight line along the X-direction with a uniform width W_{B-BL}, and the second portion is a straight line along the X-direction but with a main portion of a first width W_{B-BL1} and jog portions of a second width W_{B-BL2}. Since the first width W_{B-BL1} is smaller than the uniform width W_{B-BL}, the second portion exhibits less parasitic capacitance. The second width W_{B-BL2} may equal to, smaller than, or larger than the uniform width W_{B-BL} in various emebodiments. In the illustrated embodiment, the second width W_{B-BL2} is equal to the uniform width W_{B-BL}.

The first portion of a backside bit line (B-BL or B-BLB) feeds a number of Q-1 SRAM cells located closer to the I/O region 34, and the second portion feeds a number of N-Q+1 (defined as P) SRAM cells located further from the I/O region 34. In some embodiments, Q=N-63, meaning the last 64 (P=64) SRAM cells are fed by the narrower portion of a backside bit line, while rest of the N-64 SRAM cells in the same row are fed by the wider portion of a backside bit line. In some embodiments, Q=N-31, meaning the last 32 (P=32) SRAM cells are fed by the narrower portion of a backside bit line, while rest of the N-32 SRAM cells in the same row are fed by the wider portion of a backside bit line. In some embodiments, P is larger than 0 and not larger than 64 (0<P≤ 64). This range is not arbitrary and not trivial, as the last 64 SRAM cells may suffer from the parasitic capacitance the most. In furtherance of some embodiments, P is not less than 32 and not larger than 64 (32≤P≤64). In some embodiments, P may equal to a quarter of N (P=N/4), meaning a last quarter of the SRAM cells at the far end in reference to the I/O periphery are fed by a narrower portion of a backside bit line. In some other embodiments, P may equal to a half of N (P=N/2), meaning a last half of the SRAM cells at the far end in reference to the I/O periphery are fed by a narrower portion of a backside bit line. The transition from the larger width W_{B-BL} to the smaller width W_{B-BL1} may occur on the cell boundary line between Column Q-1 and Column Q. Alternatively, the transition of the widths may locate inside the cell boundary of the SRAM cells at the Column Q-1 or inside the cell boundary of the SRAM cells at the Column Q (as illustrated in FIG. 13).

Since the metal line width affects parasitic capacitance which may hinder the circuit speed, the smaller width W_{B-BL1} reduces overall parasitic capacitance of the combination of the frontside and backside bit lines, which improves circuit speed and reduces power consumption for the SRAM cells in the last few columns of the memory array 32, without compromising the voltage headroom for the rest of the SRAM cells along the bit lines. Meanwhile, the larger width W_{B-BL} reduces the resistance of the backside bit lines and thus the overall resistance of the combination of the frontside and backside bit lines, which increases voltage headroom along the bit line control signal path and improves signal integrity. Even though the larger width W_{B-BL} introduces more parasitic capacitance for the first few columns of the memory array 32, the benefits of having a less voltage drop for all the SRAM cells along the bit lines outweigh the slight circuit speed tradeoffs due to having slightly more parasitic capacitance.

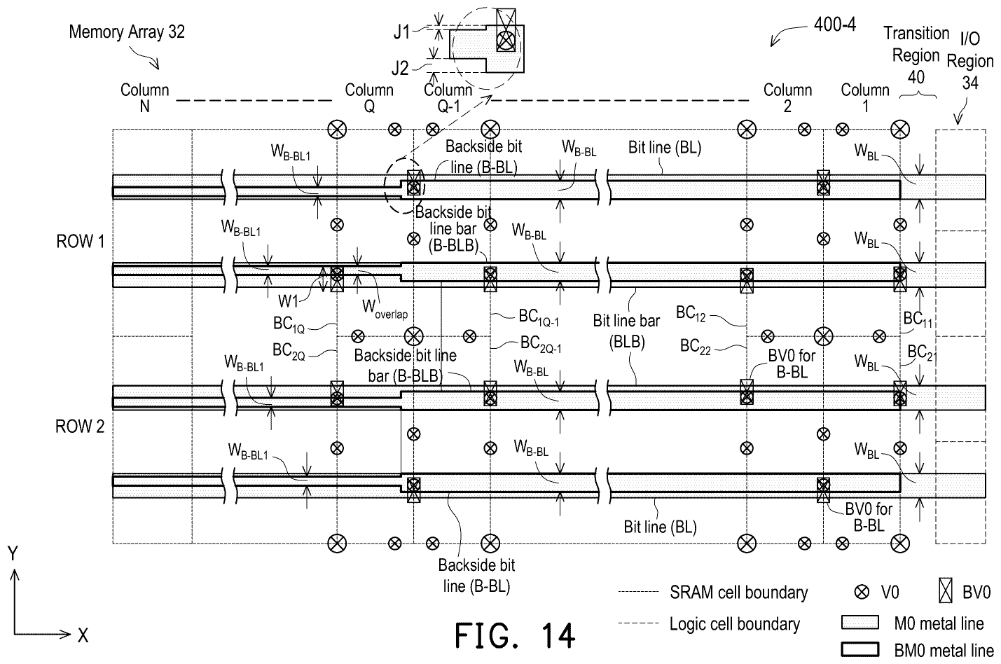

As discussed above with reference to FIG. 9, the jog portions of the backside bit lines (B-BL or B-BLB) are to provide sufficient contact area between the backside signal lines and the backside vias. In furtherance of the embodiment as illustrated in FIG. 13, if the second portion of the backside bit lines can have sufficient contact area with the backside vias without the jogs, the jog portions may be omitted. Such an embodiment is illustrated in the layout 400-4 as shown in FIG. 14. In the layout 400-4, the backside vias have a length along the Y-direction substantially similar to the width W1 of an active region, and the second portion of the backside bit lines overlaps with the backside via for a width Wₒᵥₑᵣₗₐₚ along the Y-direction. If a ratio of width Wₒᵥₑᵣₗₐₚ to width W1 is about 0.3 to about 0.7, the second portion of the backside bit lines (B-BL or B-BLB) is considered as providing sufficient contact area, and the jog portions may be optionally omitted. To better align with the backside vias, edges of the second portion of the backside bit liens (B-BL or B-BLB) may be offset from edges of the first portion. FIG. 14 illustrates an enlarged area where the transition from the first portion to the second portion occurs. A first distance J1 denotes a first distance along the Y-direction between first edges of the first portion and the second portion, and a second distance J2 denotes a second distance along the Y-direction between second edges of the first portion and the second portion. The centerline of the second portion is also offset from the centerline of the first portion to provide more overlapping area with the backside vias, such that J1 is smaller than J2 (0<J1<J2). As a comparison, in FIG. 13, with jog portions to provide sufficient overlapping area, J2 may take the value of zero (J2=0) such that second edges of the first portion and the second portion may be aligned.

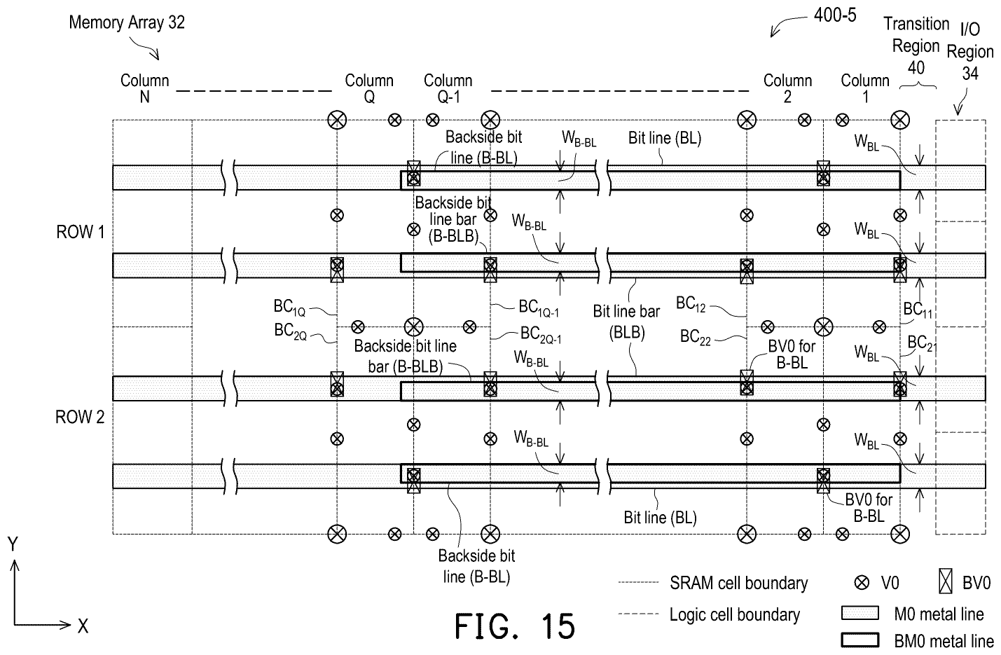

In furtherance of the embodiment as illustrated in FIG. 14, since the SRAM cells from Column Q to Column N are more sensitive to parasitic capacitance but less sensitive to resistance, the second portion of the backside bit lines may be omitted. Such an embodiment is illustrated in the layout 400-5 as shown in FIG. 15. In the layout 400-5, each of the frontside bit lines (BL or BLB) is a straight line along the X-direction with a uniform width W_{BL}. Each of the backside bit lines (B-BL or B-BLB) has only a first portion (or segment) coupled to the SRAM cells from Column 1 to Column Q-1 without having a second portion (or segment) coupled to the SRAM cells from Column Q to Column N. The first portion can be a straight line along the X-direction with a uniform width WB-BL (as shown in FIG. 15) or a straight line along the X-direction but with a main portion of a first width WB-BL1 and jog portions of a second width W_{B-BL2} (as shown in FIG. 9). In other words, a combination of the frontside and backside bit lines feeds a number of Q-1 SRAM cells located closer to the I/O region 34, and the frontside bit lines solely feed a number of N-Q+1 (P) SRAM cells located further from the I/O region 34. As shown in FIG. 15, the backside bit lines (B-BL or B-BLB) may terminate inside the cell boundary of the SRAM cells at the Column Q to ensure a good contact with the backside vias located at the cell boundary line between Column Q-1 and Column Q. Without the second portion of the backside bit lines (B-BL or B-BLB), less parasitic capacitance resides for the SRAM cells located in the far end from the I/O region 34, which improves circuit speed.

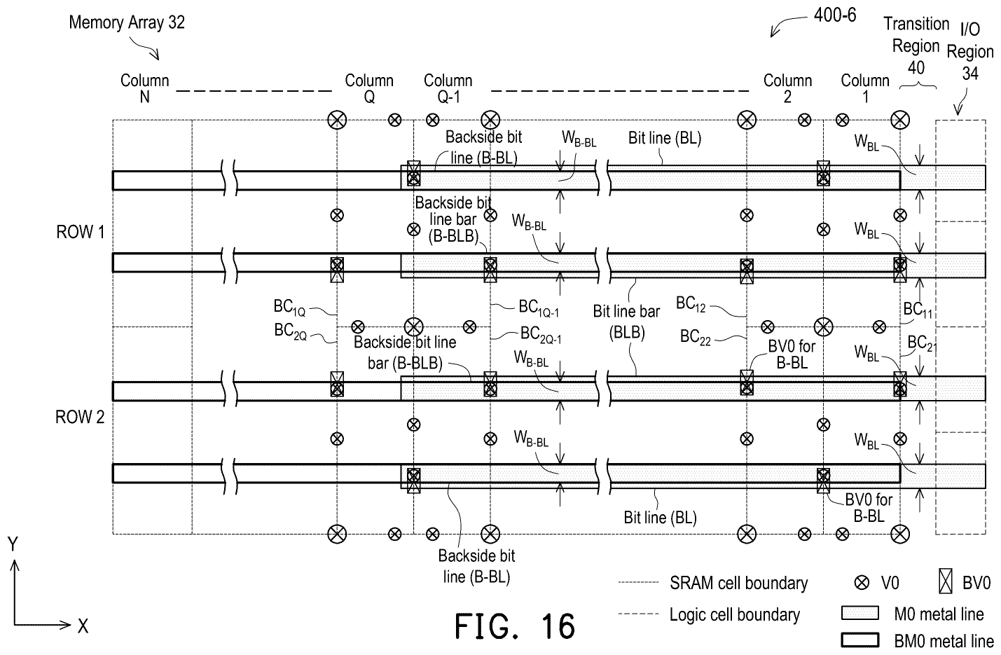

In furtherance of the embodiment as illustrated in FIG. 15, since the SRAM cells from Column Q to Column N are more sensitive to parasitic capacitance but less sensitive to resistance, the frontside bit lines (BL or BLB) may be omitted for the last few columns of the SRAM cells. Such an embodiment is illustrated in the layout 400-6 as shown in FIG. 16. In the layout 400-6, each of the backside bit lines (B-BL or B-BLB) can be a straight line along the X-direction with a uniform width W_{B-BL} (as shown in FIG. 16) or a straight line along the X-direction but with a main portion of a first width W_{B-BL1} and jog portions of a second width W_{B-BL2} (as shown in FIG. 9). Each of the frontside bit lines (B-BL or B-BLB) has only a first portion (or segment) coupled to the SRAM cells from Column 1 to Column Q-1 without a second portion (or segment) coupled to the SRAM cells from Column Q to Column N. The first portion can be a straight line along the X-direction with a uniform width W_{BL}. In other words, a combination of the frontside and backside bit lines feeds a number of Q-1 SRAM cells located closer to the I/O region 34, and the backside bit lines alone feed a number of N-Q+1 (P) SRAM cells located further from the I/O region 34. As shown in FIG. 16, the frontside bit lines (BL or BLB) may terminate inside the cell boundary of the SRAM cells at the Column Q to ensure a good contact with the frontside vias located at the cell boundary line between Column Q-1 and Column Q. Without the second portion of the frontside bit lines (BL or BLB), less parasitic capacitance resides for the SRAM cells located in the far end from the I/O region 34, which improves circuit speed.

The present disclosure also contemplates other possible combinations of the frontside and backside bit lines. For example, a first one third of the SRAM cells at the near end in reference to the I/O periphery may be fed by a combination of the frontside and backside bit lines with respective uniform widths, a second one third of the SRAM cells at the middle of the memory array may be fed by a combination of the frontside backside bit lines with a uniform width and backside bit lines with jog portions and thus a reduced width, and the last one third of the SRAM cells at the far end in reference to the I/O periphery may be fed by the frontside bit lines solely.

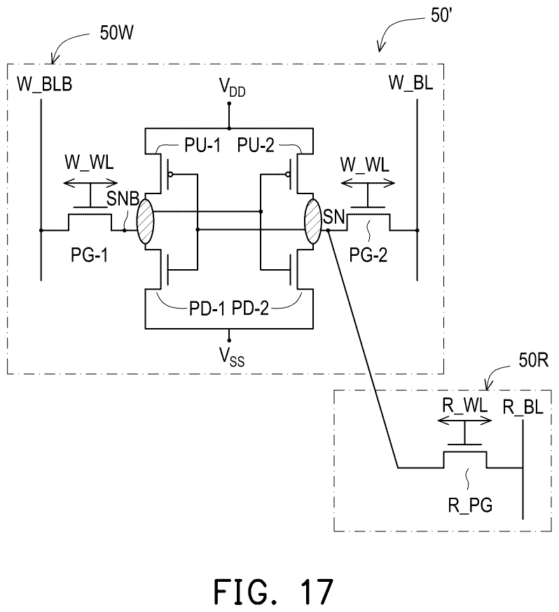

The present disclosure also contemplates a memory array formed of SRAM cells other than the single-port (SP) six-transistor (6T) SRAM cell 50 as illustrated in FIG. 3. For example, the single-port SRAM cell and/or multi-port SRAM cell may include various number of transistors to meet the performance needs, such as including six transistors (6T), seven transistors (7T), eight transistors (8T), ten transistors (10T), or even more. FIG. 17 illustrates an example circuit schematic for a two-port SRAM cell 50′ that includes seven transistors (7T). The two-port SRAM cell 50′ includes a write-port 50W and a read-port 50R. The write-port 50W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors.

The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power voltage VDD, and the sources of the pull-down transistors PD-1 and PD-2 are coupled to a voltage VSS, which may be an electrical ground in some embodiments.

The storage node SN of the data latch is coupled to a bit line W_BL of the write-port 50W through the pass-gate transistor PG-2, and the complementary storage node SNB is coupled to a complementary bit line W_BLB of the write-port 50W through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write-port 50W.

The read-port 50R of the SRAM cell 50′ includes a read-port pass-gate transistor (R-PG) coupled between the bit line R_BL and the storage node SN (or to the gates of the transistors PU-1 and PD-1). The gate of the read-port pass-gate transistor R-PG is coupled to a word line R_WL of the read-port 50R. In the illustrated embodiment, the transistor R-PG is a p-type transistor. That is, in the two-port SRAM cell 50′, the pass-gate transistors in a write-port are n-type transistors, and the pass-gate transistor in a read-port is a p-type transistor.

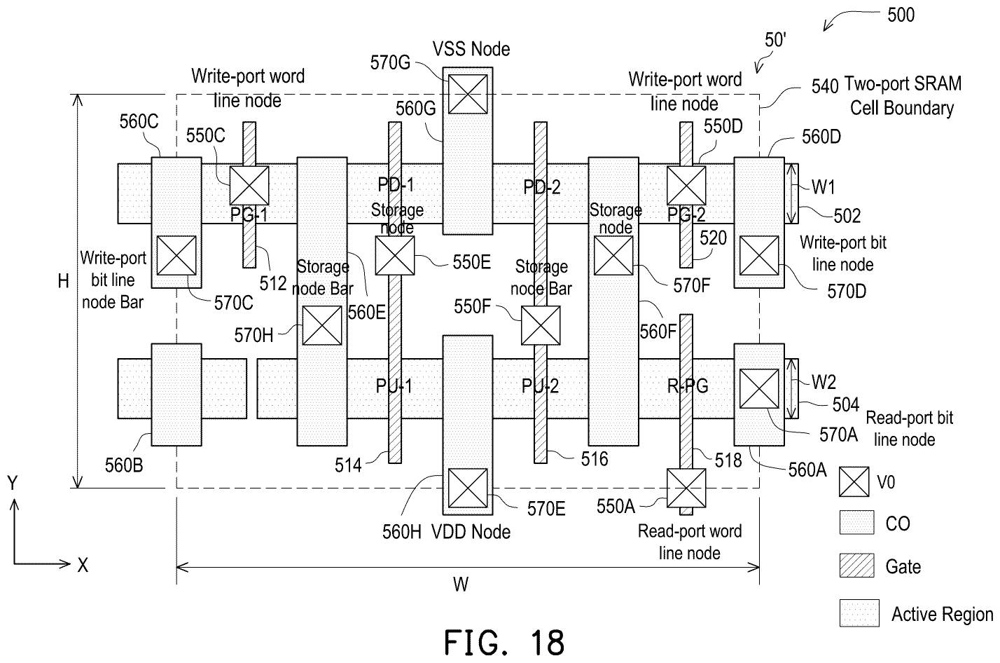

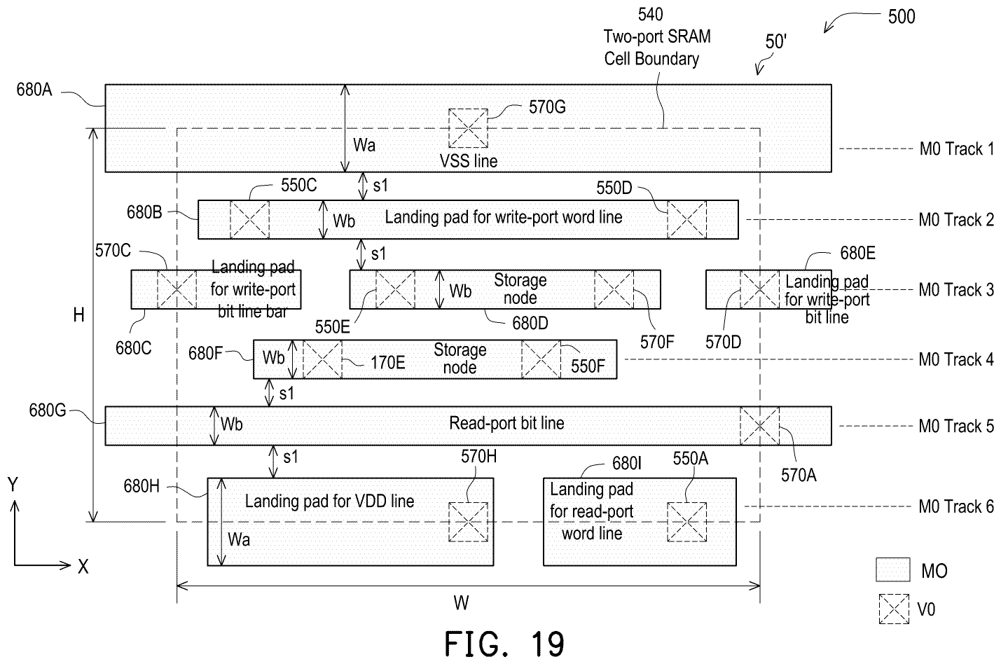

FIGS. 18 and 19 illustrate a layout 500 of the SRAM cell 50′ as in FIG. 17, in which FIG. 18 illustrates DL level, CO level, and V0 level of the layout 500 and FIG. 19 illustrates V0 level and M0 level of the layout 500. The two-port SRAM cell 50′ includes active regions 502 and 504. The active regions 502, 504 each extend lengthwise in the X-direction in FIG. 18. The active region 502 are a components of the write-port 50W, and the active region 504 has a side portion as a component of the read-port 50R and rest portion as a component of the write-port 50W. In other words, the active region 504 is shared by the read-port 50R and the write-port 50W. In the illustrated embodiment, the active region 504 belong to the transistors PU-1, PU-2, R-PG, which are PMOS devices. As such, the active region 504 is formed over an n-well. Meanwhile, the active region 502 belongs to the transistors PG-1, PD-1, PD-2, PG-2, which are NMOS devices. As such, the active region 502 is formed over a p-well (or a p-type substrate). The active region 502 has a width W1 along the Y-direction, and the active region 504 has a width W2 along the Y-direction. In various embodiment, the width W1 may be smaller than, equal to, or larger than the width W2, depending on design and performance needs. In the illustrated embodiment, width W1 is equal to width W2.

The two-port SRAM cell 50′ further includes gate structures 512, 514, 516, 518, and 520. The gate structures 512-520 each extend lengthwise in the Y-direction. The gate structures 512, 514, 516, and 520 are components of the write-port 50W. The gate structure 518 is a component of the read-port 50R. The gate structures 514, 516 each extend through the two active regions 502, 504. As such, the gate structure 514 is shared by the transistors PD-1 and PU-1, and the gate structure 516 is shared by the transistors PD-2 and PU-2.

A boundary 540 of the two-port SRAM cell 50′ is illustrated using broken lines. Note that some of the active regions and gate structures may extend beyond the illustrated boundary 540, since these active regions and gate structures may also form components of other adjacently located SRAM cells as well. For example, the gate structure 518 extends beyond the boundary 540 as shown in FIG. 18. The boundary 540 is longer in the X-direction than in the Y-direction. In other words, the boundary 540 may be rectangular. The first dimension of the boundary 540 along the X-direction is denoted as a cell width W, and the second dimension of the boundary 540 along the Y-direction is denoted as a cell height H. Where the two-port SRAM cell 50′ is repeated in a memory array, the cell width W may represent and be referred to as a memory cell pitch in the memory array along the X-direction, and the cell height H may represent and be referred to as a memory cell pitch in the memory array along the Y-direction.

A gate contact 550A electrically connects a gate of the read-port pass-gate transistor R-PG (formed by the gate structure 518) to the read-port word line node (R_WL). A gate contact 550C electrically connects a gate of the write-port pass-gate transistor PG-1 (formed by the gate structure 512) to the write-port word line node (W_WL). A gate contact 550D electrically connects a gate of the write-port pass-gate transistor PG-2 (formed by the gate structure 520) to the write-port word line node (W_WL). A gate contact 550E electrically connects a gate of the write-port pull-down transistor PD-1 (formed by the gate structure 514) and a gate of the write-port pull-up transistor PU-1 (also formed by the gate structure 514) to the storage node (SN). A gate contact 550F electrically connects a gate of the write-port pull-down transistor PD-2 (formed by the gate structure 516) and a gate of the write-port pull-up transistor PU-2 (also formed by the gate structure 516) to the complementary storage node (SNB).

A source/drain contact 560A and a source/drain contact via 570A landing thereon electrically connect a source region of the read-port pass-gate transistor R-PG to the read-port bit line node (R_BL). A source/drain contact 560B lands on a source/drain region adjacent to a fin-cut feature and stays electrically floating, as there is no corresponding source/drain contact via landing thereon. A source/drain contact 560C and a source/drain contact via 570C landing thereon electrically connect a source region of the write-port pass-gate transistor PG-1 to the write-port complementary bit line node (W_BLB). A source/drain contact 560D and a source/drain contact via 570D landing thereon electrically connect a source region of the write-port pass-gate transistor PG-2 to the write-port bit line node (W_BL). A source/drain contact 560E and a source/drain contact via 570E landing thereon electrically connect a common drain region of the write-port pass-gate transistor PG-1 and the write-port pull-down transistor PD-1 together with a drain region of the write-port pull-up transistor PU-1 to the complementary storage node (SNB). A source/drain contact 560F and a source/drain contact via 570F landing thereon electrically connect a common drain region of the write-port pass-gate transistor PG-2 and the write-port pull-down transistor PD-2 together with a common drain region of the write-port pull-up transistor PU-2 and the read-port pass-gate transistor R-PG to the storage node (SN). A source/drain contact 560G and a source/drain contact via 570G landing thereon electrically connect a common source region of the write-port pull-down transistor PD-1 and the write-port pull-down transistor PD-2 to the electrical ground node Vss. A source/drain contact 560H and a source/drain contact via 570H landing thereon electrically connect a common source region of the write-port pull-up transistor PU-1 and the write-port pull-up transistor PU-2 to the power voltage node VDD. In the illustrated embodiment, the source/drain contacts 560A-560H each are elongated and have a longitudinal direction in the Y-direction, which is parallel to the extending directions of gate structures.

The storage node SN includes the gate contact 550E and the source/drain contact via 570F positioned on two opposing sides of the gate structure 516. As to discuss in further detail below, a metal line at the M0 level extends in the X-direction to across the gate structure 516 and connects the gate contact 550E and the source/drain contact via 570F. In other words, an M0 metal line hangs over the gate structure 516 and provide the function of cross coupling between the gate contact 550E and the source/drain contact via 570F. Therefore, in the layout 500, the gate contact 550E and the source/drain contact via 570F are positioned as being level in the Y-direction, such that a metal line extending in the X-direction may connect both. Similarly, the complementary storage node (storage node bar) SNB includes the gate contact 550F and the source/drain contact via 570E positioned on two opposing sides of the gate structure 514. As to discuss in further detail below, another metal line at the M0 level extends in the X-direction to across the gate structure 514 and connects the gate contact 550F and the source/drain contact via 570E. In other words, another M0 metal line hangs over the gate structure 514 and provide the function of cross coupling between the gate contact 550F and the source/drain contact via 570E. Therefore, in the layout 500, the gate contact 550F and the source/drain contact via 570E are positioned as being level in the Y-direction, such that a metal line extending in the X-direction may connect both.

FIG. 19 illustrates the V0 level and M0 level of the layout 500 of the metal interconnect structures of the two-port SRAM cell 50′. At the M0 level, the SRAM cell 50′ includes a plurality of metal tracks arranged in parallel. Particularly, in the illustrated embodiment of the layout 500, the SRAM cell 50′ includes six metal tracks arranged in order from first (M0 Track 1) to sixth (M0 Track 6) along the Y-direction. The center lines of the metal tracks are represented by the dotted lines in FIG. 19.

In the layout 500, the first metal track “M0 Track 1” includes a global metal line 680A, which is a VSS line electrically coupled to the source/drain contact via 570G. The VSS line 680A is disposed on an upper edge of the SRAM cell 50′ and may be shared with an adjacent SRAM cell. The second metal track “M0 Track 2” includes a local metal line 680B as a landing pad for the write-port word line (W_WL). The local metal line 680B is fully within the SRAM cell 50′ and electrically connects to the gate contact 550C and the gate contact 550D. The third metal track “M0 Track 3” includes three local metal lines 680C, 680D, and 680E. The local metal line 680C provides a landing pad for the write-port complimentary bit line (W_BLB). The local metal line 680C extends beyond a left edge of the SRAM cell 50′ and may be shared with an adjacent SRAM cell. The local metal line 680D is fully within the SRAM cell 50′, which belongs to the storage node (SN) and provides cross-coupling between the gate contact 550E and the source/drain contact via 570F. As discussed above, the local metal line 680D crosses over the gate structure 516. The local metal line 680E provides a landing pad for the write-port bit line (W_BL). The local metal line 680E extends beyond a right edge of the SRAM cell 50′ and may be shared with an adjacent SRAM cell. The fourth metal track “M0 Track 4” includes a local metal line 680F. The local metal line 680F is fully within the SRAM cell 50′, which belongs to the complementary storage node (SNB) and provides cross-coupling between the gate contact 550F and the source/drain contact via 570E. As discussed above, the local metal line 680F crosses over the gate structure 516. The fifth metal track “M0 Track 5” includes a global metal line 680G, which is a red-port bit line (R_BL) and electrically couples to the source/drain contact via 570A. The sixth metal track “M0 Track 6” includes local metal lines 680H and 680I. The local metal line 680H provides a landing pad for VDD line, which is electrically coupled to the source/drain contact via 570H. The local metal line 680H is disposed on a lower edge of the SRAM cell 50′ and may be shared with an adjacent SRAM cell. The local metal line 680I provides a landing pad for the read-port word line (R_WL), which is electrically coupled to the gate contact 550A. The local metal line 680I is disposed on a lower edge of the SRAM cell 50′ and may be shared with an adjacent SRAM cell.

A width of the VSS line 680A is denoted as Wa with one half of Wa in one SRAM cell and another half of Wa in the adjacent SRAM cell. A width of the landing pad for the VDD line 680H and a width of the landing pad for the read-port word line 680I may be substantially the same as the VSS line 680A with one half of Wa in one SRAM cell and another half of Wa in the adjacent SRAM cell. The other M0 metal lines 680B-680G may each have the same width denoted as Wb. The spacing between two adjacent M0 metal lines may be uniform and denoted as s1. Thus, the SRAM cell height H equals Wa+4×Wb+5×S1. Compared with the layout 200 of the single-port SRAM cell 50 that has a cell height H corresponding to eleven M0 metal tracks (as shown in FIG. 11 or FIG. 12), the layout 500 of the two-port SRAM cell 50′ has a cell height H corresponding to six metal tracks. Thus, the two-port SRAM cell 50′ and the logic cell (as shown in FIG. 11 or FIG. 12) may have the same cell height (H=CH), allowing each two-port SRAM cell 50′ to directly abut a corresponding logic cell.

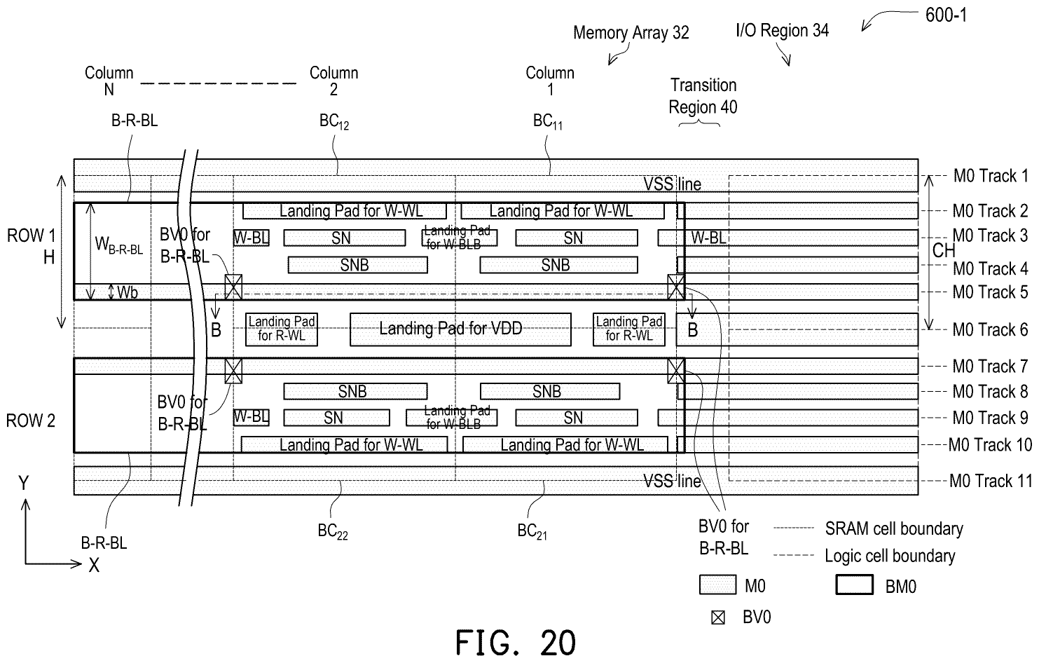

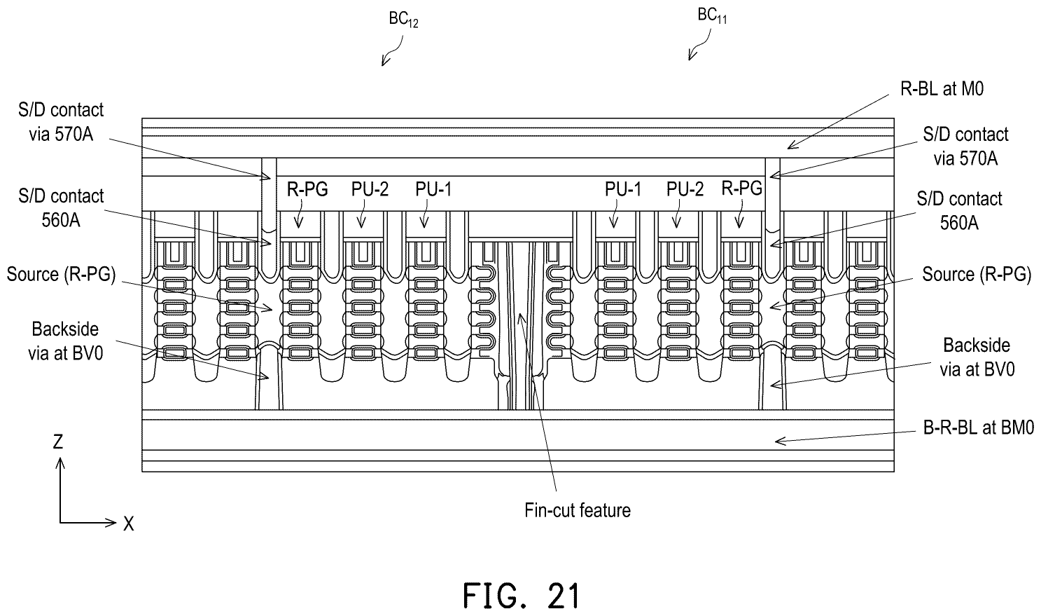

Reference is now made to FIGS. 20 and 21, collectively. FIG. 20 illustrates M0 level, BV0 level, and BM0 level of a layout 600-1 of a portion of the memory macro 30 (FIG. 2), which includes first two rows (Rows 1-2) of the memory array 32 and a portion of the logic cells in the I/O circuit (or referred to as I/O region) 34. FIG. 20 has been simplified for the sake of clarity to better understand the inventive concepts of the present disclosure. For example, some features including well regions, active regions, gate structures, S/D contacts, and vias are omitted in FIG. 20. FIG. 21 illustrates a cross-sectional view of the SRAM array taken along line B-B in FIG. 20, in accordance with some embodiments of the present disclosure.

Local metal lines at M0 level of the first two columns and first two rows (i.e., BC₁₁, BC₁₂, BC₂₁, BC₂₂) of the memory array 32 (FIG. 2) are shown but omitted in other columns to better illustrate the embodiment. Each SRAM cell in the array may use the layout 500 of the SRAM cell 50′ as depicted in FIGS. 18 and 19. As discussed above, the two-port SRAM cell 50′ and the logic cell may have the same cell height (H=CH). The metal tracks in the SRAM cells are aligned with the metal tracks in the logic cells, allowing the metal lines in the logic cells to extend into the SRAM cells. Thus, there is no need for edge cells between the memory array 32 and the I/O region 34 to provide metal transitions for the metal lines at the M0 level. Taking the SRAM cells BC₁₁ and BC₂₁ at Column 1 as an example, the M0 Track 1 includes a VSS line extending through the first SRAM cell and the first logic cell. The M0 Track 2 includes a landing pad for W-WL inside the first SRAM cell and a metal line as a signal line inside the first logic cell. The M0 Track 3 includes a landing pad for W-BLB, a local metal line for SN, and a metal line as the W-BL in the first logic cell that extends into the first SRAM cell and merges with the landing pad for W-BL. The M0 Track 4 includes the local metal line for SNB in the first SRAM cell and a metal line as a signal line inside the first logic cell. The M0 Track 5 includes a metal line as R-BL extending through the first SRAM cell and the first logic cell. The M0 Track 6 includes a landing pad for VDD, a landing pad for R-WL, and a meta line as the VDD line inside the logic cells. The M0 Track 7 includes a metal line as R-BL extending through the second SRAM cell and the second logic cell. The M0 Track 8 includes the local metal line for SNB in the second SRAM cell and a metal line as a signal line inside the second logic cell. The M0 Track 9 includes a landing pad for W-BLB, a local metal line for SN, and a metal line as the W-BL in the second logic cell that extends into the second SRAM cell and merges with the landing pad for W-BL. The M0 Track 10 includes a landing pad for W-WL inside the second SRAM cell and a metal line as a signal line inside the second logic cell. M0 Track 11 includes a VSS line extending through the second SRAM cell and the second logic cell.

The layout 600-1 also includes backside vias at BV0 level disposed under and electrically connected to the source/drain feature of the read-port pass-gate transistors R-PG and the backside read-port bit line B-R-BL at BM0 level disposed under and electrically connected to the backside vias. Therefore, the frontside read-port bit line R-BL and the backside read-port bit line B-R-BL are electrically coupled to each other through an electrical path including the backside via, the source/drain feature of the read-port pass-gate transistors R-PG, the source/drain contact 560A, and the source/drain contact via 570A. Since the backside read-port bit lines B-R-BL are formed under the SRAM cells, the dimensions of the backside read-port bit lines B-R-BL may be flexibly adjusted to achieve satisfactory performance. That is, the parasitic capacitance and parasitic resistance of the read-port bit lines may be optimized by adjusting the dimensions (e.g., width) of the backside read-port bit lines B-R-BL. For example, the width W_{B-R-BL} of the backside read-port bit lines B-R-BL may be adjusted to provide a satisfactory resistance. In the illustrated embodiment in FIG. 20, width W_{B-R-BL} of the backside read-port bit lines B-R-BL is larger than width Wb of the frontside read-port bit lines R-BL (W_{B-R-BL}>Wb). Particularly, the backside read-port bit lines B-R-BL along the Y-direction expands from the M0 Track 2 to the M0 Track 5, taking a width of about 4×Wb+3×S1 (W_{B-R-BL}=4×Wb+3×S1).

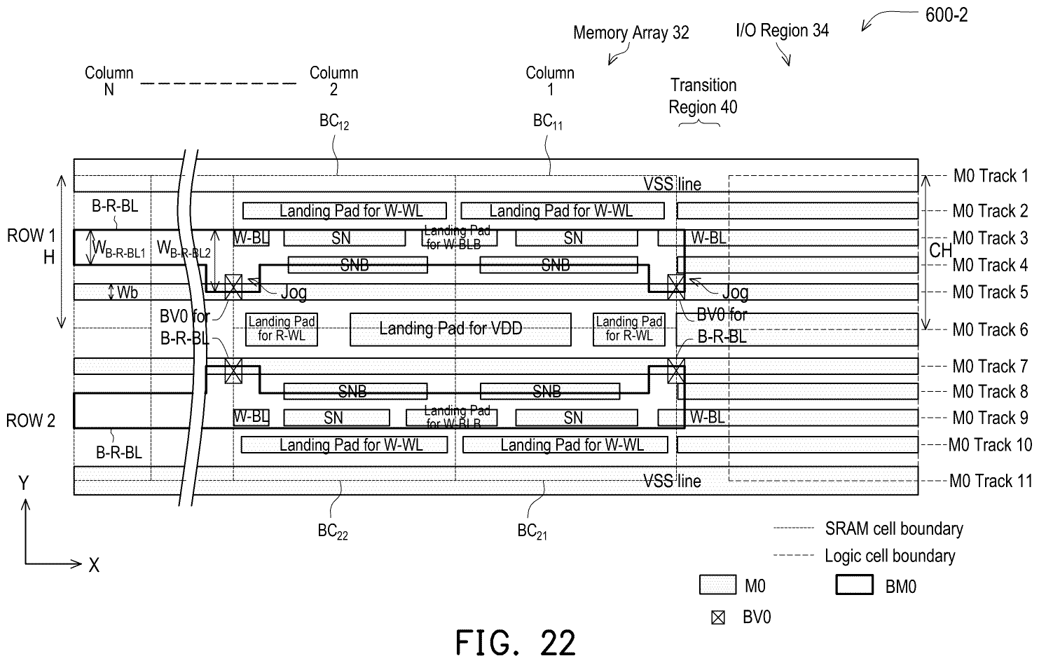

FIG. 22 illustrates an alternative layout 600-2, in accordance with some embodiments of the present disclosure. The layout 600-2 represented in FIG. 22 is similar to the layout 600-1 represented in FIG. 20, while provides reduced line width, larger line-to-line spacing, and thus less parasitic capacitance in the backside read-port bit lines. One difference between FIGS. 20 and 22 is that shapes of the backside read-port bit lines B-R-BL are different. More specifically, different from the backside read-port bit line B-R-BL in FIG. 20 that have a rectangular shape and a uniform width, the backside read-port bit line B-R-BL in FIG. 22 have a non-uniform width. The backside read-port bit line B-R-BL in FIG. 22 each include a main portion extending lengthwise along the X-direction and having a width W_{B-R-BL1} and jog portions protruding from the main portion along the Y-direction. The backside read-port bit line B-R-BL has a width W_{B-R-BL2} measured at the jog portions. The jog portions provide sufficient contact area between the backside signal lines and the backside vias, allowing the main portion of the backside signal lines to shrink and thus increasing the line-to-line spacing. State differently, the jog portions may just partially overlap with the respective backside vias or fully overlap with the respective backside vias depending on design needs. In the illustrated embodiment as shown in FIG. 22, the backside read-port bit line B-R-BL is positioned at the center of the SRAM cell (centerline of B-R-BL at half of the cell heigh H), and the jog portions partially overlap with the backside vias landing on the backside of the source/drain features of the pass-gate transistors R-PG. In various embodiments, a ratio of the width W_{B-R-BL1} to a width W2 of the active region 504 on which the pass-gate transistor R-PG is formed is about 0.5 to about 2 (0.5<W_{B-R-BL1}/W2<2). This range is not arbitrary or trivial. Having the ratio in this range keeps a balance between the active region widths for current driving capability in high performance and/or high current transistor designs and the parasitic resistance and capacitance requirements for the backside signal lines.

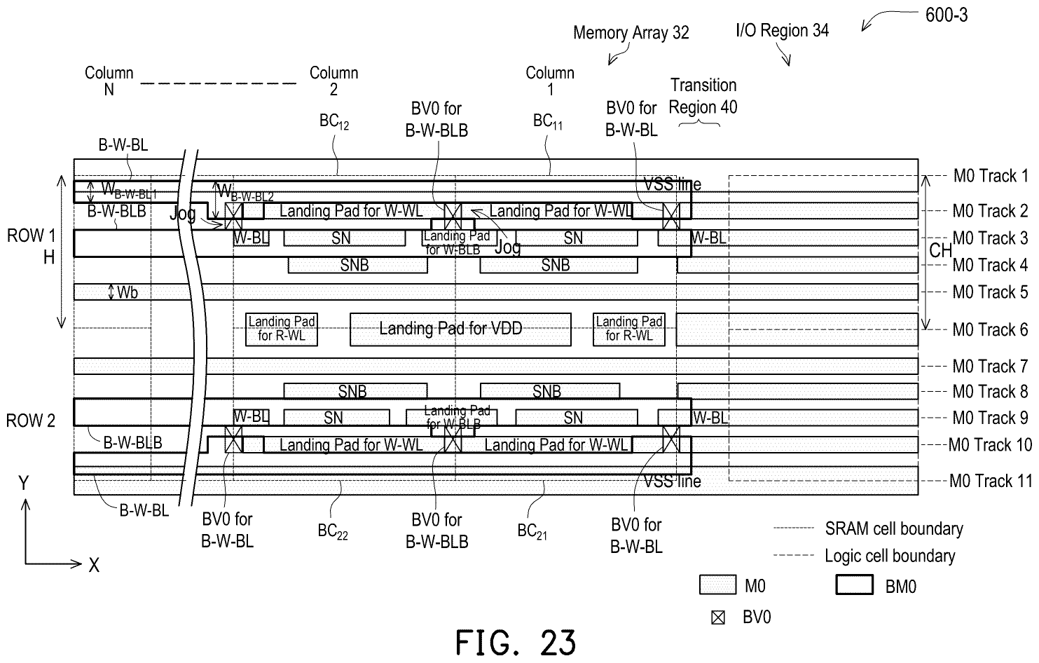

FIG. 23 illustrates an alternative layout 600-3, in accordance with some embodiments of the present disclosure. The layout 600-3 as depicted in FIG. 23 is similar to the layout 600-1 as depicted in FIG. 20 and the layout 600-2 as depicted in FIG. 22. One difference is that backside vias are formed under the source/drain features of the write-port pass-gate transistors PG-1 and PG2, and backside signal lines are devoted to backside write-port bit lines (B-W-BL and B-W-BLB) other than backside read-port bit lines B-R-BL. In the illustrated embodiment as shown in FIG. 23, the backside write-port bit lines (B-W-BL and B-W-BLB) have a non-uniform width. The backside write-port bit lines (B-W-BL and B-W-BLB) each include a main portion extending lengthwise along the X-direction and having a width W_{B-W-BL1} and jog portions protruding from the main portion along the Y-direction. The backside write-port bit lines B-W-BL and B-W-BLB have a width W_{B-W-BL2} measured at the jog portions. The jog portions provide sufficient contact area between the backside signal lines and the backside vias, allowing the main portion of the backside signal lines to shrink and thus increasing the line-to-line spacing. State differently, the jog portions may just partially overlap with the respective backside vias or fully overlap with the respective backside vias depending on design needs. In various embodiments, a ratio of width W_{B-W-BL1} to width W1 of the active region 502 on which the pass-gate transistors PG-1 and PG-2 are formed is about 0.3 to about 2 (0.3<W_{B-W-BL1}/W1<2). This range is not arbitrary or trivial. Having the ratio in this range keeps a balance between the active region widths for current driving capability in high performance and/or high current transistor designs and the parasitic resistance and capacitance requirements for the backside signal lines.

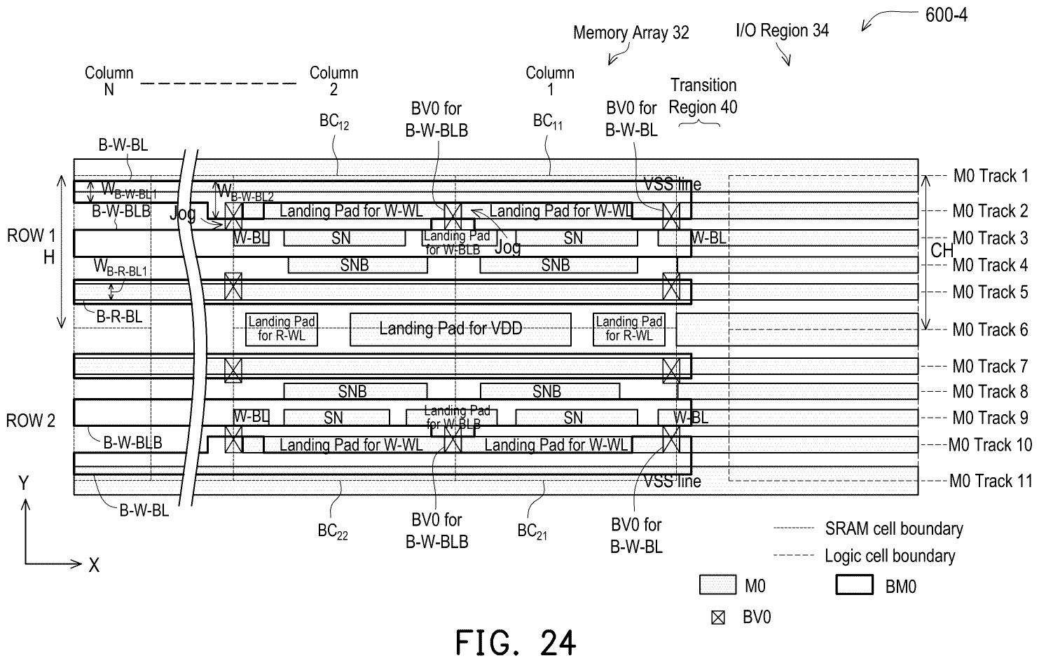

FIG. 24 illustrates an alternative layout 600-4, in accordance with some embodiments of the present disclosure. The layout 600-4 as depicted in FIG. 24 is similar to the layout 600-2 as depicted in FIG. 22 and the layout 600-3 as depicted in FIG. 23. One difference is that other than the layout 600-2 in which backside signal lines are devoted to backside read-port bit lines B-R-BL or the layout 600-3 in which backside signal lines are devoted to backside write-port bit lines B-W-BL and B-W-BLB, the layout 600-4 includes backside signal lines devoted to both the backside read-port bit lines B-R-BL and backside write-port bit lines B-W-BL and B-W-BLB and respective backside vias. In the illustrated embodiment as shown in FIG. 24, each of the backside signal lines may partially overlap with the respective backside vias to increase line-to-line spacing as an effort to reduce parasitic capacitance. The backside write-port bit line B-W-BL, the backside write-port bit line bar B-W-BLB, and the backside read-port bit line B-R-BL may be evenly spaced from each other along the Y-direction, as illustrated in FIG. 24. Further, as shown in FIG. 24, the backside read-port bit lines B-R-BL has a uniform width W_{B-R-BL1} without jog portions, and the backside write-port bit line B-W-BL and the backside write-port bit line B-W-BLB has a main portion with a width W_{B-W-BL1} and jog portions. In various embodiments, a ratio of width W_{B-R-BL1} to width W2 of the active region 504 on which the pass-gate transistor R-PG is formed is about 0.3 to about 2 (i.e., 0.3<W_{B-R-BL1}/W2<2), and a ratio of width W_{B-W-BL1} to width W1 of the active region 502 on which the pass-gate transistors PG-1 and PG-2 are formed is about 0.3 to about 2 (i.e., 0.3<W_{B-W-BL1}/W1<2). These ranges are not arbitrary or trivial. Having the ratios in these ranges keeps a balance between the active region widths for current driving capability in high performance and/or high current transistor designs and the parasitic resistance and capacitance requirements for the backside signal lines. In some embodiments, width W1 is equal to width W2.

In the illustrated exemplary layouts 600-1, 600-2, 600-3, and 600-4, the backside signal lines (e.g., B-R-BL, B-W-BL, and/or B-W-BLB) each couple to (or feed) all the SRAM cells in the same row. The present disclosure also contemplates that the backside signal lines (e.g., B-R-BL, B-W-BL, and/or B-W-BLB) each couple to (or feed) a portion but not all of the SRAM cells in the same row, which is similar to the discussion above with reference to the layouts 400-5 and 400-6. For example, in the same row, a number of Q-1SRAM cells at the near end in reference to the I/O periphery may be fed by a combination of the frontside bit lines (e.g., R-BL, W-BL, and/or W-BLB) and backside bit lines (e.g., B-R-BL, B-W-BL, and/or B-W-BLB), while a number of N-Q+1 (defined as P) SRAM cells located at the far end in reference to the I/O periphery may be fed by the frontside bit lines (e.g., R-BL, W-BL, and/or W-BLB) without backside bit lines. In some embodiments, Q=N-31, meaning the last 32 (P=32) SRAM cells are fed by the frontside bit lines solely, while rest of the N-32 SRAM cells in the same row are fed by the combination of frontside and backside bit lines. In some embodiments, P is larger than 0 and not larger than 64 (0<P≤64). This range is not arbitrary and not trivial, as the last 64 SRAM cells may suffer from the parasitic capacitance the most. In furtherance of some embodiments, P is not less than 32 and not larger than 64 (32≤P≤64). In some embodiments, P may equal to a quarter of N (P=N/4), meaning a last quarter of the SRAM cells at the far end in reference to the I/O periphery are fed by the frontside bit lines alone. In some other embodiments, P may equal to a half of N (P=N/2), meaning a last half of the SRAM cells at the far end in reference to the I/O periphery are fed by the frontside bit lines solely.

Various embodiments of the present disclosure illustrate a bit line structure providing a combination of frontside and backside bit lines. Some of the exemplary bit lines may have a non-uniform width (e.g., different widths along a bit line) in an SRAM array. In one embodiment, an SRAM array may feature different combinations of frontside bit lines and backside bit lines for memory cells at different distances with reference to an I/O periphery, which enhances circuit performance. Different embodiments may have different advantages, and no particular advantage is required of any embodiment.

In one example aspect, the present disclosure provides a semiconductor device. The semiconductor device includes a logic cell, a memory array comprising a plurality of memory cells, a frontside interconnect structure disposed over the memory cells and comprising a frontside bit line, and a backside interconnect structure disposed under the memory cells and comprising a backside bit line. The memory cells and the logic cell are arranged in a row, and a first plurality of the memory cells are positioned closer to the logic cell than a second plurality of the memory cells. The frontside bit line is coupled to each of the memory cells arranged in the row. The backside bit line is coupled to at least the first plurality of the memory cells, and the frontside bit line is coupled to the backside bit line through a source/drain feature of a pass-gate transistor of one of the first plurality of the memory cells. In some embodiments, the backside bit line is free of coupling to the second plurality of the memory cells. In some embodiments, a number of the second plurality of the memory cells is less than a number of the first plurality of the memory cells. In some embodiments, the backside bit line has a first portion coupled to the first plurality of the memory cells and a second portion coupled to the second plurality of the memory cells, and the first portion of the backside bit line is wider than the second portion of the backside bit line. In some embodiments, a number of the second plurality of the memory cells is less than a number of the first plurality of the memory cells. In some embodiments, the frontside bit line and the backside bit line have different widths. In some embodiments, the frontside bit line is wider than the backside bit line. In some embodiments, the backside bit line is wider than the frontside bit line. In some embodiments, the frontside bit line has a uniform width, and the backside bit line has a non-uniform width. In some embodiments, the frontside bit line fully overlaps with a frontside source/drain contact landing on the source/drain feature, and the backside bit line partially overlaps with a backside source/drain contact landing under the source/drain feature.

Another aspect of the present disclosure provides a semiconductor device. The semiconductor device includes a memory array comprising a plurality of memory cells arranged in a row, a frontside interconnect structure disposed over the memory cells and comprising a frontside bit line, and a backside interconnect structure disposed under the memory cells and comprising a backside bit line. The frontside bit line is coupled to at least some of the memory cells arranged in the row. The backside bit line is coupled to at least some of the memory cells arranged in the row. In a top view of the semiconductor device, the frontside bit line partially overlaps with the backside bit line. In a cross-sectional view of the semiconductor device, the frontside bit line and the backside bit line are both coupled to a source/drain feature of a pass-gate transistor of one of the memory cells. In some embodiments, in the cross-sectional view of the semiconductor device, the backside bit line is thicker than the frontside bit line. In some embodiments, in the cross-sectional view of the semiconductor device, the frontside bit line is wider than the backside bit line. In some embodiments, the backside bit line is a first backside bit line, the backside interconnect structure comprises a second backside bit line, and in the cross-sectional view of the semiconductor device, the first backside bit line is wider than the second backside bit line. In some embodiments, the frontside bit line is coupled to each of the memory cells arranged in the row, and the backside bit line is free of coupling to at least one of the memory cells arranged in the row. In some embodiments, the backside bit line is coupled to each of the memory cells arranged in the row, and the frontside bit line is free of coupling to at least one of the memory cells arranged in the row. In some embodiments, the frontside bit line has a uniform width, and the backside bit line has a main portion and jogs protruding from the main portion.

Yet another aspect of the present disclosure provides a semiconductor device. The semiconductor device includes a memory array including memory cells arranged in M rows and N columns, M and N each being an integer, a logic region adjacent the memory array and coupled to the memory cells, and an interconnect structure disposed over the memory array and the logic region. The interconnect structure includes a frontside signal line suspended directly above one of the M rows of the memory cells and a backside signal line disposed directly under the one of the M rows of the memory cells. The frontside signal line is coupled to each of the memory cells of the one of the M rows. The backside signal line includes a first segment coupled to the memory cells in a first column to a (Q-1)^{th} column of the one of the M rows and a second segment coupled to the memory cells in a Q^{th} column to a Nth column of the one of the M rows. Q is an integer larger than 1 and smaller than N. The first column is located closer to the logic region than the Nth column. The first segment has a first width and the second segment has a second width that is smaller than the first width. In some embodiments, N is larger than 128 and N-Q+1 is not larger than 64. In some embodiments, N-Q+1 is one fourth of N.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A semiconductor device, comprising:
a first cell of a first type;
an array comprising a plurality of second cells of a second type different from the first type, wherein the second cells and the first cell are arranged in a row, and wherein a first plurality of the second cells are positioned closer to the first cell than a second plurality of the second cells;
a frontside interconnect structure disposed over the second cells and comprising a frontside signal line, wherein the frontside signal line is electrically coupled to each of the second cells arranged in the row; and
a backside interconnect structure disposed under the second cells and comprising a backside signal line, wherein the backside signal line is electrically coupled to at least the first plurality of the second cells, and wherein the frontside signal line is electrically coupled to the backside signal line.

2. The semiconductor device of claim 1, wherein the first cell of the first type is configured to provide a logic function, and the second cells of the second type are configured to provide a memory storage function.

3. The semiconductor device of claim 2, wherein the frontside and backside signal lines are bit lines.

4. The semiconductor device of claim 1, wherein when viewed from top the frontside signal line extends into a boundary of the first cell.

5. The semiconductor device of claim 4, wherein when viewed from top the backside signal line is spaced apart from the boundary of the first cell along a longitudinal direction of the row.

6. The semiconductor device of claim 1, wherein the frontside signal line is electrically coupled to the backside signal line through a plurality of source/drain features in the second cells.

7. The semiconductor device of claim 1, wherein the backside signal line is free of electrical coupling to the second plurality of the second cells.

8. The semiconductor device of claim 7, wherein a number of the second plurality of the second cells is less than a number of the first plurality of the second cells.

9. The semiconductor device of claim 1, wherein the frontside signal line has a uniform width, and the backside signal line has a non-uniform width.

10. The semiconductor device of claim 1, wherein a thickness of the backside signal line is greater than a thickness of the frontside signal line.

11. A semiconductor device, comprising:
a plurality of cells of a same type arranged in a row;
a frontside interconnect structure disposed over the cells and comprising a frontside signal line, wherein the frontside signal line is electrically coupled to a first number of the cells arranged in the row; and
a backside interconnect structure disposed under the cells and comprising a backside signal line, wherein the backside signal line is electrically coupled to a second number of the cells arranged in the row,
wherein in a top view of the semiconductor device, the frontside signal line overlaps with the backside signal line, and
wherein in a cross-sectional view of the semiconductor device, the frontside signal line and the backside signal line are both electrically coupled to a plurality of source/drain features in the cells.

12. The semiconductor device of claim 11, wherein in the top view a width of the frontside signal line is greater than a width of the backside signal line.

13. The semiconductor device of claim 11, wherein in the top view a width of the backside signal line is greater than a width of the frontside signal line.

14. The semiconductor device of claim 11, wherein the first number is greater than the second number.

15. The semiconductor device of claim 11, wherein the second number is greater than the first number.

16. The semiconductor device of claim 11, wherein a difference between the first number and the second number is a quarter of a total number of the cells arranged in the row.

17. A semiconductor device, comprising:
a first region comprising an array that includes a plurality of first cells arranged in M rows and N columns;
a second region adjacent to the first region, the second region comprising a plurality of second cells different from the first cells;
a frontside interconnect structure disposed over the first and second regions, the frontside interconnect structure including a frontside signal line over one of the M rows of the first cells and electrically coupled to a first number of the first cells in the one of the M rows; and
a backside interconnect structure disposed under the first and second regions, the backside interconnect structure including a backside signal line under the one of the M rows of the first cells and electrically coupled to a second number of the first cells in the one of the M rows,
wherein the first number is different from the second number, and the frontside signal line is electrically coupled to the backside signal line.

18. The semiconductor device of claim 17, wherein the backside signal line is coupled to each of the first cells of the one of the M rows, and wherein:
the backside signal line includes a first segment coupled to the first cells in a first column to a (Q-1)th column of the one of the M rows and a second segment coupled to the first cells in a Qth column to a Nth column of the one of the M rows,
Q is an integer larger than 1 and smaller than N,
the first column is located closer to the second region than the Nth column, and
the first segment has a first width and the second segment has a second width that is smaller than the first width.

19. The semiconductor device of claim 18, wherein N is greater than 128 and N-Q+1 is not greater than 64.

20. The semiconductor device of claim 18, wherein the first number is greater than the second number.
